(19) United States
(12) Patent Application Publication
(10) Pub. No.: US 2024/0162397 A1
(43) Pub. Date: May 16, 2024

(54) DISPLAY DEVICE

(71) Applicant: Samsung Display Co., LTD., Yongin-si (KR)

(72) Inventors: Se Hyun LEE, Yongin-si (KR); Kyung Bae KIM, Yongin-si (KR); Kwi Hyun KIM, Yongin-si (KR); Jin Joo HA, Yongin-si (KR)

(73) Assignee: Samsung Display Co., LTD., Yongin-si (KR)

(21) Appl. No.: 18/507,334

(22) Filed: Nov. 13, 2023

(30) Foreign Application Priority Data
Nov. 14, 2022 (KR) 10-2022-0151822

(51) Int. Cl. H01L 33/60; H01L 25/075; H01L 33/38; H01L 33/50; H01L 33/52; H01L 33/62

(52) U.S. Cl. CPC H01L 33/60; H01L 25/0753; H01L 33/38; H01L 33/50; H01L 33/52; H01L 33/62

(57) ABSTRACT

A display device includes a pixel electrode disposed on a substrate, a bank layer disposed on the substrate and the pixel electrode, and separating an emission area from a non-emission area, light emitting elements each arranged on the pixel electrode and including a first semiconductor layer, a second semiconductor layer, and an active layer disposed between the first semiconductor layer and the second semiconductor layer, a first capping layer disposed on the pixel electrode and surrounding side surfaces of the light emitting elements, a first reflective layer disposed on the first capping layer and surrounding the side surfaces of the light emitting elements, a first via layer disposed on the first reflective layer, a second via layer disposed on the first via layer, and a common electrode disposed on the second via layer and the light emitting elements.

### CROSS REFERENCE TO RELATED APPLICATION(S)

This application claims priority to and the benefits of Korean Patent Application No. 10-2022-0151822 under 35 U.S.C. § 119, filed on Nov. 14, 2022, in the Korean Intellectual Property Office (KIPO), the entire contents of which are incorporated herein by reference.

### BACKGROUND

### 1. Technical Field

The disclosure relates to a display device.

### 2. Description of the Related Art

The importance of display devices has steadily increased with the development of multimedia technology. In response thereto, various types of display devices such as an organic light emitting display (OLED), a liquid crystal display (LCD), and the like have been used.

A display device is a device for displaying an image, and includes a display panel, such as an organic light emitting display panel, a liquid crystal display panel, or the like. The light emitting display panel may include light emitting elements, e.g., light emitting diodes (LED), and examples of the light emitting diode include an organic light emitting diode (OLED) using an organic material as a light emitting material, an inorganic light emitting diode using an inorganic material as a light emitting material, and the like.

### SUMMARY

Aspects of the disclosure provide a display device capable of improving light output efficiency of a light emitting element.

However, aspects of the disclosure are not restricted to those set forth herein. The above and other aspects of the disclosure will become more apparent to one of ordinary skilled in the art to which the disclosure pertains by referencing the detailed description of the disclosure given below.

According to an aspect of the disclosure, a display device may include a pixel electrode disposed on a substrate, a bank layer disposed on the substrate and the pixel electrode, and separating an emission area from a non-emission area, light emitting elements each arranged on the pixel electrode and comprising a first semiconductor layer, a second semiconductor layer, and an active layer disposed between the first semiconductor layer and the second semiconductor layer, a first capping layer disposed on the pixel electrode and surrounding side surfaces of the light emitting elements, a first reflective layer disposed on the first capping layer and surrounding the side surfaces of the light emitting elements, a first via layer disposed on the first reflective layer, a second via layer disposed on the first via layer, and a common electrode disposed on the second via layer and the light emitting elements.

In an embodiment, each of the light emitting elements may further include an insulating layer surrounding side surfaces of the first semiconductor layer, the active layer, and the second semiconductor layer, and the first capping layer may contact the insulating layer.

In an embodiment, the first reflective layer may be spaced apart from the light emitting elements, and may contact a surface of the first capping layer.

In an embodiment, the first semiconductor layer may be disposed adjacent to the pixel electrode, and the first capping layer and the first reflective layer may surround a side surface of the first semiconductor layer, a side surface of the active layer, and a side surface of the second semiconductor layer.

In an embodiment, the first capping layer and the first reflective layer may surround at least a portion of the side surface of the second semiconductor layer.

In an embodiment, a height of each of the first capping layer and the first reflective layer may be less than heights of the light emitting elements.

In an embodiment, a height of the first capping layer and a height of the first reflective layer may be same.

In an embodiment, the first capping layer and the first reflective layer in the emission area may be spaced apart from another first capping layer and another first reflective layer in an adjacent emission area and may overlap the emission area in a plan view.

In an embodiment, the first via layer may contact a top surface of the first reflective layer, and be spaced apart from an edge of the first reflective layer, and the second via layer may cover the first via layer, the first reflective layer, and the first capping layer.

In an embodiment, the display device may further include partition walls each disposed on the common electrode and overlapping the bank layer in a plan view, a second reflective layer disposed on the partition walls, a wavelength conversion layer disposed between the partition wall and the partition wall, and a color filter layer disposed on the wavelength conversion layer.

According to an aspect of the disclosure, a display device may include a pixel electrode disposed on a substrate, a bank layer disposed on the substrate and the pixel electrode, and separating an emission area from a non-emission area, light emitting elements each arranged on the pixel electrode and comprising a first semiconductor layer, a second semiconductor layer, and an active layer disposed between the first semiconductor layer and the second semiconductor layer, a first via layer disposed between the pixel electrode and the light emitting elements, a first reflective layer disposed on the first via layer and surrounding side surfaces of the light emitting elements, a second via layer disposed on the first via layer and the first reflective layer, and a common electrode disposed on the second via layer and the light emitting elements.

In an embodiment, each of the light emitting elements may further include a connection electrode disposed between the pixel electrode and the first semiconductor layer, and a height of the first via layer and a height of the connection electrode may be same.

In an embodiment, a top surface of the first via layer and a bottom surface of the first semiconductor layer may contact each other.

In an embodiment, each of the light emitting elements may further include an insulating layer surrounding side surfaces of the first semiconductor layer, the active layer, and the second semiconductor layer, and the first reflective layer may contact the insulating layer.

In an embodiment, the first reflective layer may surround side surfaces of the first semiconductor layer, the active layer, and the second semiconductor layer.

In an embodiment, the display device may further include a second reflective layer disposed on the first via layer. The first via layer may include a protrusion overlapping the bank layer in a plan view, and the second reflective layer may be disposed on a side surface of the protrusion.

In an embodiment, the first reflective layer may surround a side surface of the second semiconductor layer, and a bottom surface of the first reflective layer may be disposed higher than a top surface of the active layer.

In an embodiment, each of the first reflective layer and the second reflective layer may surround the light emitting elements, and may have a closed loop shape in a plan view.

In an embodiment, the second reflective layer may not overlap the first semiconductor layer and the active layer in a horizontal direction.

In an embodiment, a bottom surface of the second reflective layer may be disposed higher than a top surface of the active layer.

The display device according to an embodiment may include a first reflective layer surrounding a side surface of the light emitting element, so that light emitted from the light emitting element and emitted to the side surface may be reflected upward. Accordingly, light output efficiency of the light emitting element may be improved.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings.

FIG. 1 is a schematic plan view of a display device according to an embodiment.

FIG. 2 is a schematic layout view illustrating a circuit of a display substrate of the display device according to an embodiment.

FIG. 3 is a schematic diagram of an equivalent circuit diagram of a pixel of a display device according to an embodiment.

FIG. 4 is a schematic diagram of an equivalent circuit diagram of a pixel of a display device according to another embodiment.

FIG. 5 is a schematic diagram of an equivalent circuit diagram of a pixel of a display device according to another embodiment.

FIG. 6 is a schematic cross-sectional view illustrating a display device according to an embodiment.

FIG. 7 is a schematic enlarged view illustrating a first emission area according to an embodiment.

FIG. 8 is a schematic cross-sectional view illustrating a pixel electrode and a light emitting element according to an embodiment.

FIG. 9 is a schematic plan view illustrating emission areas of a display device according to an embodiment.

FIG. 10 is a schematic plan view illustrating multiple emission areas and multiple color filters.

FIG. 11 is a schematic cross-sectional view illustrating a display device according to another embodiment.

FIG. 12 is a schematic enlarged view illustrating a first emission area according to another embodiment.

FIG. 13 is a schematic cross-sectional view illustrating a display device according to another embodiment.

FIG. 14 is a schematic enlarged view illustrating a first emission area according to another embodiment.

FIGS. 15 to 35 are schematic diagrams illustrating a method of manufacturing a display device according to an embodiment.

FIGS. 36 to 38 are schematic diagrams illustrating a method of manufacturing a display device according to another embodiment.

FIGS. 39 to 42 are schematic diagrams illustrating a method of manufacturing a display device according to another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

In the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Each of the features of the various embodiments of the disclosure may be combined or combined with each other, in part or in whole, and technically various interlocking and driving are possible. Each embodiment may be implemented independently of each other or may be implemented together in an association.

Hereinafter, embodiments will be described with reference to the accompanying drawings.

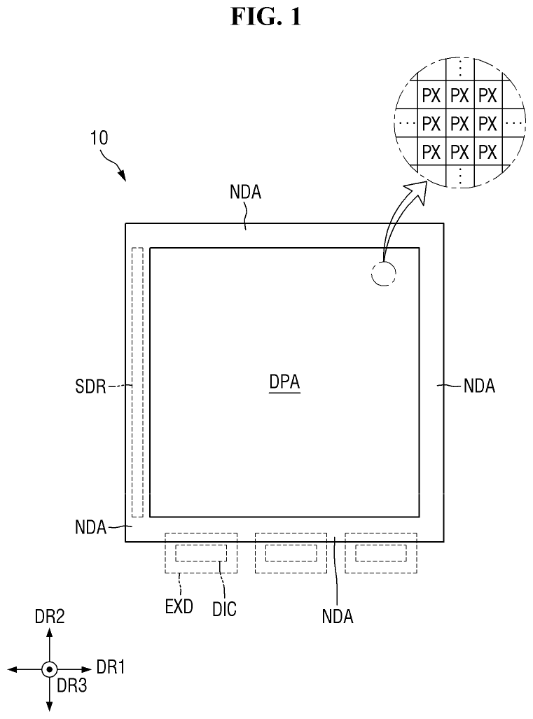

FIG. 1 is a schematic plan view of a display device according to an embodiment.

Referring to FIG. 1, a display device 10 according to an embodiment may be applied to a smartphone, a mobile phone, a tablet PC, a personal digital assistant (PDA), a portable multimedia player (PMP), a television, a game machine, a wristwatch-type electronic device, a head-mounted display, a monitor of a personal computer, a laptop computer, a car navigation system, a car's dashboard, a digital camera, a camcorder, an external billboard, an electronic billboard, a medical device, an inspection device, various household appliances such as a refrigerator, a washing machine, and the like, or an Internet-of-Things device. In the disclosure, a television (TV) is described as an example of a display device, and the TV may have a high resolution or an ultra high resolution such as HD, UHD, 4K, 8K, and the like.

The display device 10 according to an embodiment may be classified into various types according to a display method. For example, a classification of the display device may include an organic light emitting display (OLED display), an inorganic light emitting diode display (inorganic LED display), a quantum dot light emitting display (QED), a micro-LED display, a nano-LED display, a plasma display panel (PDP), a field emission displays (FED), a cathode ray display tube display (CRT display), a liquid crystal display (LCD), an electrophoretic display (EPD), and the like. Hereinafter, the organic light emitting display device will be described as an example of the display device 10, and the organic light emitting display device applied to the embodiment will be simply referred to as a display device unless special distinction is required. However, the disclosure is not limited to the organic light emitting display device, and other display devices mentioned above or known in the art may be applied within a same scope of technical spirit.

In the drawings, a first direction DR1 may be a horizontal direction of the display device 10, a second direction DR2 may be a vertical direction of the display device 10, and a third direction DR3 may be a thickness direction of the display device 10. However, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another. “Left,” “right,” “upper,” and “lower” may indicate directions in case that the display device 10 is viewed from above. For example, “right side” may be a side in the first direction DR1, “left side” may be another side in the first direction DR1, “upper side” may be a side in the second direction DR2, and “lower side” may be another side in the second direction DR2. “Upper portion” may indicate a side in the third direction DR3, and “lower portion” may indicate another side in the third direction DR3.

The display device 10 according to an embodiment may have a quadrate shape, e.g., a square shape in a plan view. In case that the display device 10 is a television, the display device 10 may have a rectangular shape with a long side positioned in the horizontal direction (e.g., first direction DR1). However, the disclosure is not limited thereto, and the long side of the display device 10 may extend in the vertical direction. In another embodiment, the display device 10 may be installed to be rotatable such that long side of the display device 10 is variably positioned to extend in the horizontal or vertical direction. Further, the display device 10 may have a circular shape, an elliptical shape, or the like.

The display device 10 may include a display area DPA and a non-display area NDA. The display area DPA may be an active area in which an image is displayed. The display area DPA may have a square shape in a plan view similar to an overall shape of the display device 10, but the disclosure is not limited thereto.

The display area DPA may include multiple pixels PX. The pixels PX may be arranged in a matrix. A shape of each pixel PX may be rectangular or square in a plan view. However, without being limited thereto, each pixel PX may have a rhombic shape of which each side is inclined with respect to a side direction of the display device 10. The pixels PX may include multiple color pixels PX. For example, the pixels PX may include a first color pixel PX of red, a second color pixel PX of green, and a third color pixel PX of blue, however, the disclosure is not limited thereto. Each color pixel PX may be alternately arranged in a stripe type or a PenTile® type.

The non-display area NDA may be disposed adjacent to the display area DPA. The non-display area NDA may be disposed around the display area DPA. The non-display area NDA may completely or partially surround the display area DPA. The display area DPA may have a square shape, and the non-display area NDA may be disposed adjacent to four sides of the display area DPA. The non-display area NDA may form a bezel of the display device 10.

In the non-display area NDA, a driving circuit or a driving element for driving the display area DPA may be disposed. In an embodiment, in the non-display area NDA disposed adjacent to a first side (lower side in FIG. 1) of the display device 10, a pad portion may be provided on a display substrate of the display device 10, and an external device EXD may be mounted on pad electrodes of the pad portion. The external devices EXD may include, e.g., a connection film, a printed circuit board, a driver integrated circuit (DIC), a connector, a wiring connection film, and the like. A scan driver SDR directly formed on the display substrate of the display device 10 may be provided in the non-display area NDA disposed adjacent to a second side (left side in FIG. 1) of the display device 10.

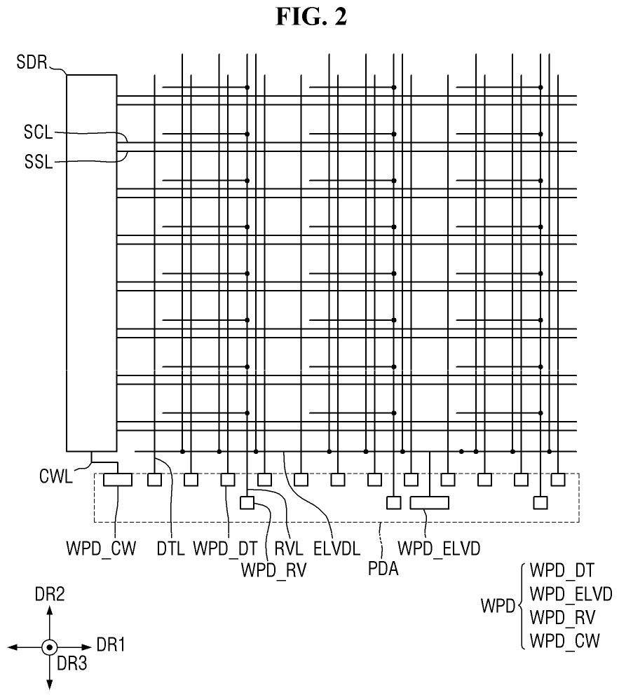

FIG. 2 is a schematic layout view illustrating a circuit of a display substrate of the display device according to an embodiment.

Referring to FIG. 2, multiple wirings may be disposed on the substrate. The wirings may include a scan line SCL, a sensing signal line SSL, a data line DTL, a reference voltage line RVL, a first power line ELVDL, and the like.

The scan line SCL and the sensing signal line SSL may extend in a first direction DR1. The scan line SCL and the sensing signal line SSL may be connected to the scan driver SDR. The scan driver SDR may include a driving circuit. The scan driver SDR may be disposed on a side of the non-display area NDA on the display substrate, but the disclosure is not limited thereto, and the scan driver SDR may be disposed on sides of the non-display area NDA. The scan driver SDR may be connected to a signal connection line CWL, and at least one end of the signal connection line CWL may form a pad WPD_CW on a first non-display area NDA and/or a second non-display area NDA which may be connected to the external devices (EXD in FIG. 1).

The data line DTL and the reference voltage line RVL may extend in a second direction DR2 intersecting the first direction DR1. The first power line ELVDL may include portions extending in the second direction DR2. The first power line ELVDL may further include a portion extending in the first direction DR1. The first power line ELVDL may have a mesh structure, but the disclosure is not limited thereto.

At least one end of the data line DTL, the reference voltage line RVL, and the first power line ELVDL may be provided with wiring pads WPD. Each wiring pad WPD may be disposed in a pad portion PDA of the non-display area NDA. In an embodiment, a wiring pad WPD_DT (hereinafter, referred to as a ‘data pad’) of the data line DTL, a wiring pad WPD_RV (hereinafter, referred to as ‘reference voltage pad’) of the reference voltage line RVL, and a wiring pad WPD_ELVD (hereinafter, referred to as a ‘first power pad’) of the first power line ELVDL may be disposed in the pad portion PDA of the non-display area NDA. In another embodiment, the data pad WPD_DT, the reference voltage pad WPD_RV, and the first power pad WPD_ELVD may be disposed in another non-display area NDA. As described above, the external devices (‘EXD’ in FIG. 1) may be mounted on the wiring pads WPD. The external devices EXD may be mounted on the wiring pads WPD by applying an anisotropic conductive film, ultrasonic bonding, or the like.

Each pixel PX on the display substrate may include a pixel driving circuit. The above-described wirings may pass through each pixel PX or a vicinity of each pixel PX to apply a driving signal to each pixel driving circuit. The pixel driving circuit may include transistors and capacitors. The number of the transistors and the capacitors of each pixel driving circuit may be variously modified. Hereinafter, the pixel driving circuit will be described in conjunction with a 3T1C structure including three transistors and a capacitor as an embodiment. However, the disclosure is not limited thereto, and another modified pixel PX structures such as a 2T1C structure, a 7T1C structure, a 6T1C structure, or the like may be adopted.

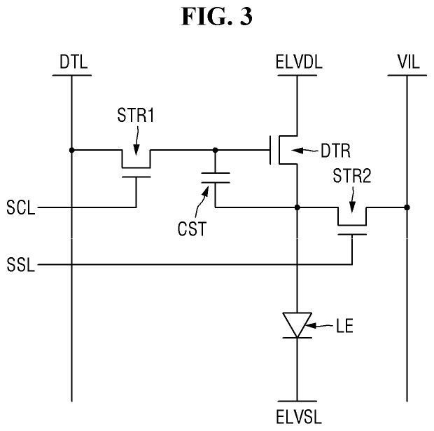

FIG. 3 is a schematic diagram of an equivalent circuit diagram of a pixel of a display device according to an embodiment.

Referring to FIG. 3, each pixel PX of the display device 10 according to an embodiment may include three transistors DTR, STR1, and STR2 and a storage capacitor CST (in addition to a light emitting element LE).

The light emitting element LE may emit light according to a current supplied through a driving transistor DTR. The light emitting element LE may be implemented as an inorganic light emitting diode, an organic light emitting diode, a micro light emitting diode, a nano light emitting diode, or the like.

A first electrode (i.e., anode electrode) of the light emitting element LE may be connected to a source electrode of the driving transistor DTR, and a second electrode (i.e., cathode electrode) of the light emitting element EMD may be connected to a second power line ELVSL to which a low potential voltage (second source voltage) lower than a high potential voltage (first source voltage) of the first power line ELVDL is supplied.

The driving transistor DTR may adjust a current flowing from the first power line ELVDL, to which the first power voltage is applied, to the light emitting element LE according to a voltage difference between a gate electrode and the source electrode. The gate electrode of the driving transistor DTR may be connected to a first electrode of a first transistor ST1, the source electrode of the driving transistor DTR may be connected to the first electrode of the light emitting element LE, and the drain electrode of the driving transistor DTR may be connected to the first power supply line ELVDL to which the first power voltage is applied.

A first transistor STR1 may be turned on by a scan signal of a scan line SCL to connect a data line DTL to the gate electrode of the driving transistor DTR. A gate electrode of the first transistor STR1 may be connected to the scan line SCL, the first electrode of the first transistor STR1 may be connected to the gate electrode of the driving transistor DTR, and a second electrode of the first transistor STR1 may be connected to the data line DTL.

A second transistor STR2 may be turned on by a sensing signal of a sensing signal line SSL to connect an initialization voltage line VIL to the source electrode of the driving transistor DTR. A gate electrode of the second transistor ST2 may be connected to the sensing signal line SSL, a first electrode of the second transistor ST2 may be connected to the initialization voltage line VIL, and a second electrode of the second transistor ST2 may be connected to the source electrode of the driving transistor DTR.

In an embodiment, the first electrode of each of the first and second transistors STR1 and STR2 may be a source electrode and the second electrode of each of the first and second transistors STR1 and STR2 may be a drain electrode, but the disclosure is not limited thereto, and may be vice versa.

The capacitor CST may be formed between the gate electrode and the source electrode of the driving transistor DTR. The storage capacitor CST may store a difference voltage between a gate voltage and a source voltage of the driving transistor DTR.

The driving transistor DTR, the first transistor STR1, and the second transistor STR2 may be formed as thin film transistors. Further, FIG. 3 illustrates that the driving transistor DTR, the first switching transistor STR1, and the second switching transistor STR2 are N-type metal oxide semiconductor field effect transistors (MOSFETs), but the disclosure is not limited thereto. For example, the driving transistor DTR, the first switching transistor STR1, and the second switching transistor STR2 may be P-type MOSFETs, or some of the driving transistor DTR, the first switching transistor STR1, and the second switching transistor STR2 may be N-type MOSFETs, while others may be P-type MOSFETs.

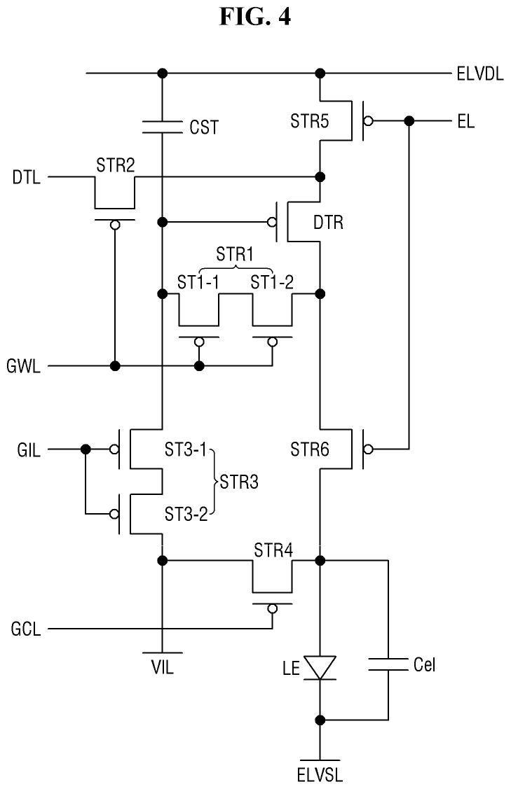

FIG. 4 is a schematic diagram of an equivalent circuit diagram of a pixel of a display device according to another embodiment.

Referring to FIG. 4, the first electrode of the light emitting element LE may be connected to a first electrode of a fourth transistor STR4 and a second electrode of a sixth transistor STR6, and the second electrode of the light emitting element LE may be connected to the second power line ELVSL. A parasitic capacitance Cel may be formed between the first electrode and the second electrode of the light emitting element LE.

Each pixel PX may include the driving transistor DTR, switch elements, and the capacitor CST. The switch elements may include first to sixth transistors STR1, STR2, STR3, STR4, STR5, and STR6.

The driving transistor DTR may include a gate electrode, a first electrode, and a second electrode. The driving transistor DTR may control a drain-source current Ids (hereinafter, referred to as “driving current”) flowing between the first electrode and the second electrode according to a data voltage applied to the gate electrode.

The capacitor CST may be formed between the gate electrode of the driving transistor DTR and a first power line ELVDL. An electrode of the capacitor CST may be connected to the gate electrode of the driving transistor DTR, and another electrode of the capacitor CST may be connected to the first power line ELVDL.

In case that a first electrode of each of the driving transistor DTR and the first to sixth transistors STR1 to STR6 is a source electrode, a second electrode of each of the driving transistor DTR and the first to sixth transistors STR1 to STR6 may be a drain electrode. As another example, in case that the first electrode of each of the driving transistor DTR and the first to sixth transistors STR1 to STR6 is a drain electrode, the second electrode of each of the driving transistor DTR and the first to sixth transistors STR1 to STR6 may be a source electrode.

In addition, the first transistor STR1 and the third transistor STR3 may include a plurality of sub-transistors. For example, in FIG. 4, the first transistor STR1 may include sub-transistors ST1-1 and ST1-2, and the third transistor STR3 may include sub-transistors ST3-1 and ST3-2. The gate electrodes of the sub-transistors ST1-1 and ST1-2 of the first transistor STR1 are connected to a write scan line GWL, and gate electrodes of the sub-transistors ST3-1 and ST3-2 of the third transistor STR3 are connected to an initialization scan line GIL, a gate electrode of the fourth transistor is connected to a control scan line GCL, and gate electrodes of the fifth and sixth transistors are connected to a light-emitting line EL, however, the embodiment is not limited thereto.

A semiconductor layer of each of the driving transistor DTR and the first to sixth transistors STR1 to STR6 may be formed of one of polysilicon, amorphous silicon, an oxide semiconductor, or the like. In case that a semiconductor layer of each of the driving transistor DTR and the first to sixth transistors STR1 to STR6 is formed of polysilicon, a process for forming the semiconductor layer may be a low temperature polysilicon (LTPS) process.

FIG. 4 illustrates that the driving transistor DTR and the first to sixth transistors STR1 to STR6 are formed of a p-type metal oxide semiconductor field effect transistor (MOSFET), but the disclosure is not limited thereto, and the driving transistor DTR and the first to sixth transistors STR1 to STR6 may be formed of an n-type MOSFET.

A first power voltage of the first power line ELVDL, a second power voltage of the second power line ELVSL, and a third power voltage of an initialization voltage line VIL may be set in consideration of characteristics of the driving transistor DTR, characteristics of the light emitting element LE, and the like.

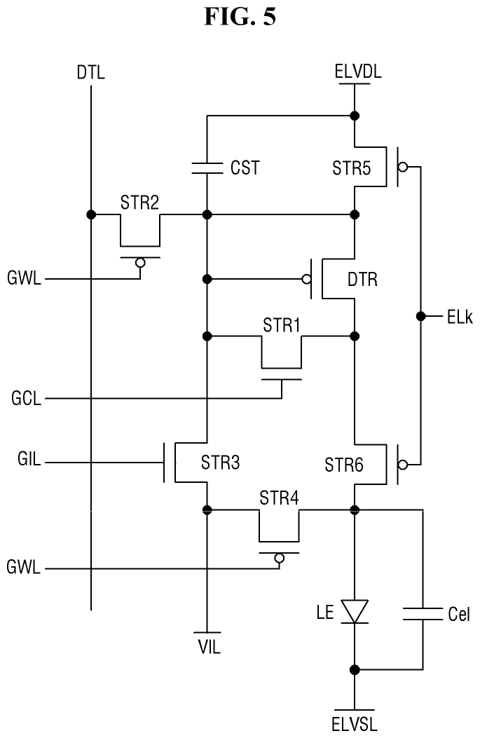

FIG. 5 is a schematic diagram of an equivalent circuit diagram of a pixel of a display device according to another embodiment.

The embodiment of FIG. 5 may be different from the embodiment of FIG. 4 in that the driving transistor DTR, the second transistor STR2, the fourth transistor STR4, the fifth transistor STR5, and the sixth transistor STR6 are formed of P-type MOSFETs, and the first transistor STR1 and the third transistor STR3 are formed of N-type MOSFETs.

Referring to FIG. 5, a semiconductor layer of each of the driving transistor DTR, the second transistor STR2, the fourth transistor STR4, the fifth transistor STR5 and the sixth transistor STR6 configured as P-type MOSFETs may be formed of polysilicon, whereas a semiconductor layer of each of the first transistor STR1 and the third transistor STR3 configured as N-type MOSFETs may be formed of an oxide semiconductor.

The embodiment of FIG. 5 may be different from the embodiment of FIG. 4 in that the gate electrode of the fourth transistor STR4 is connected to a write scan line GWL, and the gate electrode of the first transistor ST1 is connected to a control scan line GCL. Further, in FIG. 5, since the first transistor STR1 and the third transistor STR3 are formed of N-type MOSFET, the scan signal of a gate high voltage may be applied to the control scan line GCL and an initialization scan line GIL. On the contrary, the second transistor STR2, the fourth transistor STR4, the fifth transistor STR5, and the sixth transistor STR6 may be formed as P-type MOSFETs, so that a scan signal of a gate low voltage may be applied to the write scan line GWL and an emission line ELk.

It should be noted that the equivalent circuit diagram of the pixel PX according to the above-described embodiment of the specification is not limited to those illustrated in FIGS. 3 to 5. The equivalent circuit diagram of the pixel PX according to the embodiment of the specification may be formed in other known circuit structures that those skilled in the art may employ in addition to the embodiments illustrated in FIGS. 3 to 5.

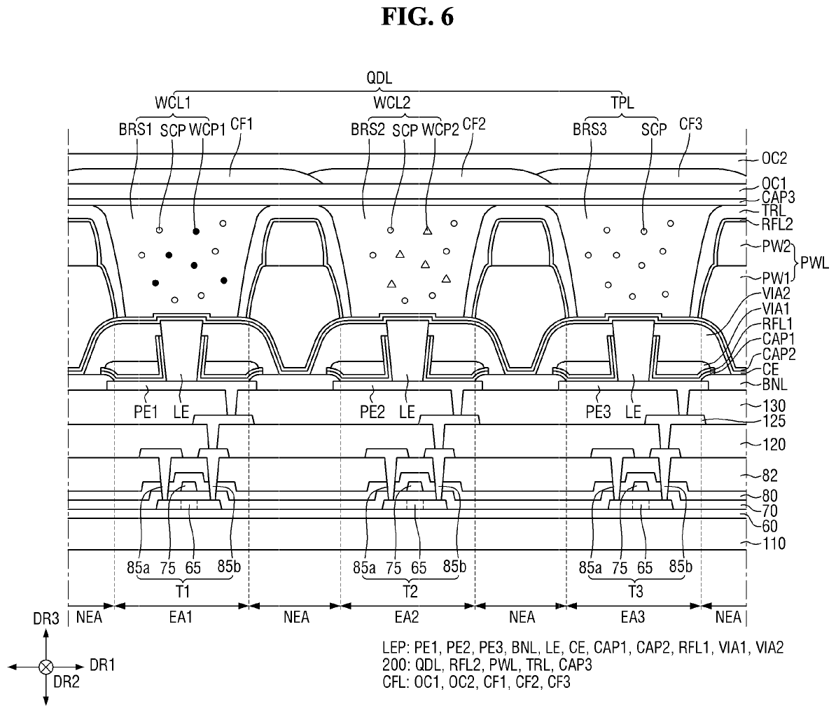

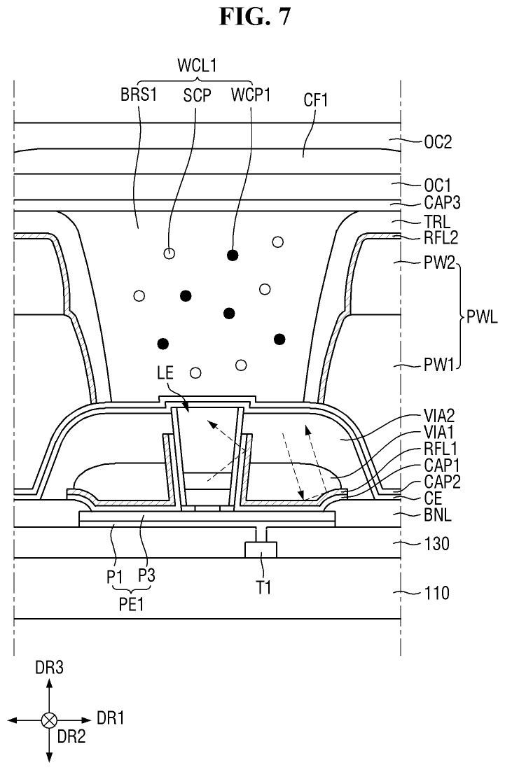

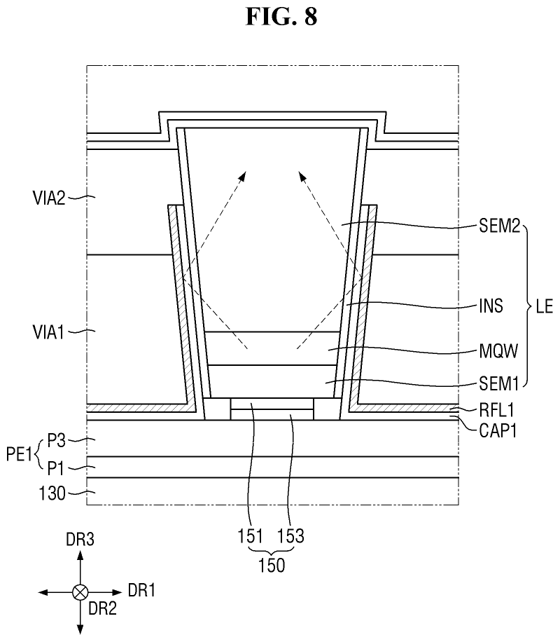

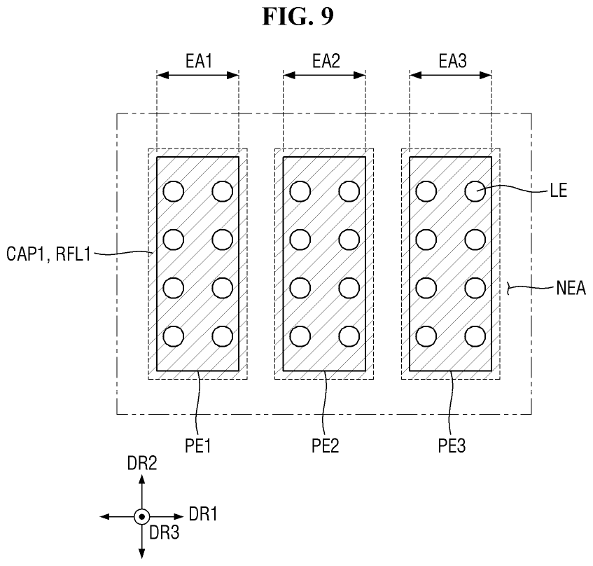

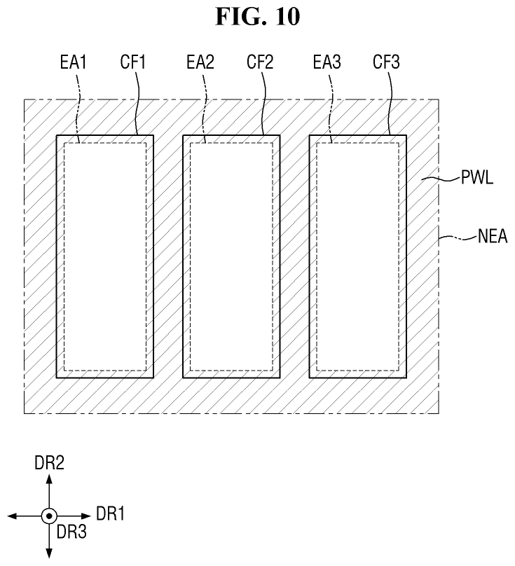

FIG. 6 is a schematic cross-sectional view illustrating a display device according to an embodiment. FIG. 7 is a schematic enlarged view illustrating a first emission area according to an embodiment. FIG. 8 is a schematic cross-sectional view illustrating a pixel electrode and a light emitting element according to an embodiment, FIG. 9 is a schematic plan view illustrating emission areas of a display device according to an embodiment, and FIG. 10 is a schematic plan view illustrating multiple emission areas and multiple color filters.

Referring to FIGS. 6 to 10, the display device 10 may include a substrate 110 and a light emitting element part LEP disposed on the substrate 110. The substrate 110 may be an insulating substrate. The substrate 110 may include a transparent material. For example, the substrate 110 may include a transparent insulating material such as glass, quartz, or the like. The substrate 110 may be a rigid substrate. However, the substrate 110 is not limited thereto. The substrate 110 may include a polymer such as polyimide or the like, and may have a flexible property such that it may be twisted, bent, folded, or rolled. Multiple emission areas EA1, EA2, and EA3 and a non-emission area NEA may be defined on the substrate 110.

Switching elements T1, T2, and T3 may be positioned on the substrate 110. In an embodiment, a first switching element T1 may be positioned in a first emission area EA1 of the substrate 110, a second switching element T2 may be positioned in a second emission area EA2 of the substrate 110, and a third switching element T3 may be positioned in the third emission area EA3 of the substrate 110. However, the disclosure is not limited thereto, and in another embodiment, at least one of the first switching element T1, the second switching element T2 and the third switching element T3 may be located in the non-emission region NEA.

In an embodiment, each of the first switching element T1, the second switching element T2, and the third switching element T3 may be a thin film transistor including amorphous silicon, polysilicon, an oxide semiconductor, or the like. Although not shown in the drawing, multiple signal lines (e.g., a gate line, a data line, a power line, and the like) that transmit signals to the switching elements T1, T2, and T3 may be further positioned on the substrate 110.

Each of the switching elements T1, T2, and T3 may include a semiconductor layer 65, a gate electrode 75, a source electrode 85a, and a drain electrode 85b.

A buffer layer 60 may be disposed on the substrate 110. The buffer layer 60 may be disposed to cover an entire surface of the substrate 110. The buffer layer 60 may include silicon nitride, silicon oxide, silicon oxynitride, the like, or a combination thereof, and may be formed as a single layer or a double layer.

The semiconductor layer 65 may be disposed on the buffer layer 60. The semiconductor layer 65 may form a channel of each of the switching elements T1, T2, and T3. The semiconductor layer 65 may include amorphous silicon, polycrystalline silicon, an oxide semiconductor, or the like. For example, the oxide semiconductor may include, for example, a binary compound (ABₓ), a ternary compound (ABₓC_{y}), or a quaternary compound (ABₓC_{y}D_{z}) including indium, zinc, gallium, tin, titanium, aluminum, hafnium (Hf), zirconium (Zr), magnesium (Mg), or the like. In an embodiment, the semiconductor layer 65 may include indium tin zinc oxide (IGZO).

A gate insulating layer 70 may be disposed on the semiconductor layer 65. The gate insulating layer 70 may include a silicon compound, a metal oxide, or the like. For example, the gate insulating layer 70 may include silicon oxide, silicon nitride, silicon oxynitride, aluminum oxide, tantalum oxide, hafnium oxide, zirconium oxide, titanium oxide, or the like. In an embodiment, the gate insulating layer 70 may include silicon oxide.

The gate electrode 75 may be disposed on the gate insulating layer 70. The gate electrode 75 may be disposed to overlap the semiconductor layer 65 in a plan view. The gate electrode 75 may include a conductive material. The gate electrode 75 may include a metal oxide such as ITO, IZO, ITZO, In₂O₃, and the like or a metal such as copper (Cu), titanium (Ti), aluminum (Al), molybdenum (Mo), tantalum (Ta), calcium (Ca), chromium (Cr), magnesium (Mg), nickel (Ni), and the like. For example, the gate electrode 75 may be formed as a Cu/Ti double layer in which an upper layer made of copper is stacked on a lower layer made of titanium, but the disclosure is not limited thereto.

A first interlayer insulating layer 80 and a second interlayer insulating layer 82 may be disposed on the gate electrode 75. The first interlayer insulating layer 80 may be disposed directly on the gate electrode 75, and the second interlayer insulating layer 82 may be disposed directly on the first interlayer insulating layer 80. Each of the first interlayer insulating layer 80 and the second interlayer insulating layer 82 may include an inorganic insulating material such as silicon oxide, silicon nitride, silicon oxynitride, hafnium oxide, aluminum oxide, titanium oxide, tantalum oxide, zinc oxide, or the like. However, the disclosure is not limited thereto, and the second interlayer insulating layer 82 may include an organic insulating material capable of flattening a stepped portion disposed under the second interlayer insulating layer 82. Although two interlayer insulating layers of the first interlayer insulating layer 80 and the second interlayer insulating layer 82 have been illustrated and described in the embodiment, the disclosure is not limited thereto, and in another embodiment, only one interlayer insulating layer may be disposed.

The source electrode 85a and the drain electrode 85b may be disposed on the second interlayer insulating layer 82. The source electrode 85a and the drain electrode 85b may contact the semiconductor layer 65 through contact holes penetrating the first interlayer insulating layer 80, the second interlayer insulating layer 82, and the gate insulating layer 70. The source electrode 85a and the drain electrode 85b may include a metal oxide such as ITO, IZO, ITZO, In₂O₃, and the like or a metal such as copper (Cu), titanium (Ti), aluminum (Al), molybdenum (Mo), tantalum (Ta), calcium (Ca), chromium (Cr), magnesium (Mg), nickel (Ni), and the like. For example, the source electrode 85a and the drain electrode 85b may be formed as a Cu/Ti double layer in which an upper layer made of copper is stacked on a lower layer made of titanium, but the disclosure is not limited thereto.

A first planarization layer 120 may be disposed on the first switching element T1, the second switching element T2, and the third switching element T3. The first planarization layer 120 may include an organic material. For example, the first planarization layer 120 may include an acrylic resin, an epoxy resin, an imide resin, an ester resin, or the like. In an embodiment, the first planarization layer 120 may include a positive photosensitive material or a negative photosensitive material.

A pixel connection electrode 125 may be disposed on the first planarization layer 120. The pixel connection electrode 125 may be disposed to correspond to each of the first switching element T1, the second switching element T2, and the third switching element T3, and may be electrically connected to each of the first switching element T1, the second switching element T2, and the third switching element T3. The pixel connection electrode 125 may connect pixel electrodes PE1, PE2, and PE3 to be described below to the above-described switching elements T1, T2, and T3. The pixel connection electrode 125 may contact the switching elements T1, T2, and T3 through contact holes penetrating the first planarization layer 120.

A second planarization layer 130 may be disposed on the first planarization layer 120 and the pixel connection electrode 125. The second planarization layer 130 may flatten a stepped portion disposed under the second planarization layer 130. The second planarization layer 130 and the first planarization layer 120 may include a same material.

The light emitting element part LEP may be disposed on the second planarization layer 130. The light emitting element part LEP may include the pixel electrodes PE1, PE2, and PE3, multiple light emitting elements LE, and a common electrode CE. The light emitting element part LEP may further include a bank layer BNL that partitions each of the emission areas EA1, EA2, and EA3, and a first via layer VIA1 and a second via layer VIA2.

The pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may serve as a first electrode of the light emitting element LE, and may be an anode electrode or a cathode electrode. The first pixel electrode PE1 may be located in the first emission area EA1, the second pixel electrode PE2 may be located in the second emission area EA2, and the third pixel electrode PE3 may be located in the third emission area EA3. In an embodiment, the first pixel electrode PE1 may overlap the first emission area EA1, the second pixel electrode PE2 may overlap the second emission area EA2, and the third pixel electrode PE3 may overlap the third emission area EA3 in a plan view.

The pixel electrodes PE1, PE2, and PE3 may be directly connected to the pixel connection electrode 125 through contact holes penetrating the second planarization layer 130, and may be electrically connected to each of the switching elements T1, T2, and T3 through the pixel connection electrode 125. The first pixel electrode PE1, the second pixel electrode PE2, and the third pixel electrode PE3 may include a metal. The metal may include, e.g., copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), the like, or a mixture thereof. Further, the first pixel electrode PE1, the second pixel electrode PE2, and the third pixel electrode PE3 may have a multi-layer structure in which two or more metal layers are stacked each other. For example, the first pixel electrode PE1, the second pixel electrode PE2, and the third pixel electrode PE3 may have a two-layer structure in which a copper layer is stacked on a titanium layer, but the disclosure is not limited thereto.

Referring to FIG. 7, in an embodiment, each of the pixel electrodes PE1, PE2, and PE3 may include a lower electrode layer P1 and an upper electrode layer P3. Hereinafter, the first pixel electrode PE1 will be described, and descriptions of the second pixel electrode PE2 and the second pixel electrode will be omitted.

The lower electrode layer P1 may be disposed at a portion (e.g., the lowermost portion) of the first pixel electrode PE1 and may be electrically connected to the first switching element T1. The lower electrode layer P1 may serve to provide adhesiveness with the second planarization layer 130 to the first pixel electrode PE1. The lower electrode layer P1 may include a metal, e.g., titanium.

The upper electrode layer P3 may be disposed on the lower electrode layer P1 and directly contact the light emitting element LE. The upper electrode layer P3 may be disposed between the lower electrode layer P1 and the light emitting element LE, and may serve to provide adhesiveness with the light emitting element LE to the first pixel electrode PE1. The upper electrode layer P3 may include a metal, e.g., copper.

The light emitting elements LE may be disposed on the first pixel electrode PE1, the second pixel electrode PE2, and the third pixel electrode PE3.

As illustrated in FIGS. 6 to 8, the light emitting elements LE may be disposed in each of the first emission area EA1, the second emission area EA2, and the third emission area EA3. The light emitting element LE may be a vertical light emitting diode element elongated in the third direction DR3. For example, a length of the light emitting element LE in the third direction DR3 may be greater than a length of the light emitting element LE in the horizontal direction. The length in the horizontal direction may indicate a length in the first direction DR1 or a length in the second direction DR2. For example, the length of the light emitting element LE in the third direction DR3 may be in a range of about 1 μm to about 5 μm. However, the disclosure is not limited thereto, and the length of the light emitting element LE in the third direction DR3 may be equal to or less than the length in the horizontal direction.

The light emitting element LE may be a micro light emitting diode element. The light emitting element LE may include a connection electrode 150, a first semiconductor layer SEM1, an active layer MQW, and a second semiconductor layer SEM2 arranged in the thickness direction of the substrate 110, for example, in the third direction DR3. The connection electrode 150, the first semiconductor layer SEM1, the active layer MQW, and the second semiconductor layer SEM2 may be sequentially stacked on top of each other in the third direction DR3. The light emitting element LE may include an insulating layer INS surrounding at least a portion of the first semiconductor layer SEM1, the active layer MQW, and the second semiconductor layer SEM2.

The light emitting element LE may have a cylindrical shape, a disk shape, or a rod shape that is longer in height than in width. However, the disclosure is not limited thereto, and the light emitting element LE may have various shapes, such as a rod shape, a wire shape, a tube shape, a polygonal prism shape (e.g., a regular cube, a rectangular parallelepiped, and a hexagonal prism), a shape extending in a direction and having a partially inclined outer surface, and the like.

The connection electrode 150 may be disposed on each of the pixel electrodes PE1, PE2, and PE3. Hereinafter, the light emitting element LE disposed on the first pixel electrode PE1 will be described as an example, but the disclosure is not limited thereto, and the light emitting elements LE disposed on the second pixel electrode PE2 and the third pixel electrode PE3 may have a same structure.

The connection electrode 150 may include a reflective layer 151 and a connection layer 153. The reflective layer 151 may serve to reflect light emitted from the active layer MQW of the light emitting element LE. The reflective layer 151 may be disposed adjacent to the active layer MQW of the light emitting element LE. The reflective layer 151 may include a metal having a conductivity and high light reflectivity. The reflective layer 151 may include, e.g., aluminum (Al), silver (Ag), the like, or an alloy thereof.

The connection layer 153 may serve to transmit an emission signal from the first pixel electrode PE1 to the light emitting element LE. The connection layer 153 may be an ohmic connection electrode. However, the disclosure is not limited thereto, and the connection layer 153 may be a Schottky connection electrode. The connection layer 153 may be disposed at a portion (e.g., the lowermost portion) of the light emitting element LE, and may be more distant from the active layer MQW than the reflective layer 151. The connection layer 153 may include at least one of gold (Au), copper (Cu), tin (Sn), silver (Ag), aluminum (Al), and titanium (Ti). For example, the connection layer 153 may include a 9:1 alloy, an 8:2 alloy, or a 7:3 alloy of gold and tin, or may include an alloy (SAC305) of copper, silver, and tin.

FIG. 8 illustrates the connection electrode 150 of the light emitting element LE has a double-layer structure of a reflective layer 151 and a connection layer 153, but the disclosure is not limited thereto. In another embodiment, the light emitting element LE may include the connection electrode 150 in which more than two layers are stacked with each other or some layers are omitted.

The first semiconductor layer SEM1 may be disposed on the connection electrode 150. The first semiconductor layer SEM1 may be disposed adjacent to the first pixel electrode PE1. The first semiconductor layer SEM1 may be a p-type semiconductor, and may include a semiconductor material having a chemical formula of AlₓGa_{y}In_{1-x-y}N (0≤x≤1, 0≤y≤1, 0≤x+y≤1). For example, the first semiconductor layer SEM1 may be one or more of p-type doped AlGaInN, GaN, AlGaN, InGaN, AlN, InN, and the like. The first semiconductor layer SEM1 may be doped with a p-type dopant, and the p-type dopant may be Mg, Zn, Ca, Se, Ba, or the like. For example, the first semiconductor layer SEM1 may be GaN doped with p-type Mg. A thickness of the first semiconductor layer SEM1 may be in a range of about 30 nm to about 200 nm in the thickness direction of the substrate 110, but the disclosure is not limited thereto.

The active layer MQW may be disposed on the first semiconductor layer SEM1. The active layer MQW may emit light by coupling of electron-hole pairs according to an electrical signal applied through the first semiconductor layer SEM1 and the second semiconductor layer SEM2. The active layer MQW may emit first light having a central wavelength band in a range of about 450 nm to about 495 nm, i.e., light of a blue wavelength band.

The active layer MQW may include a material having a single or multiple quantum well structure. In case that the active layer MQW includes a material having a multiple quantum well structure, the active layer MQW may have a structure in which multiple well layers and multiple barrier layers are alternately stacked on top of each other. The well layers may be formed of InGaN, and the barrier layers may be formed of GaN or AlGaN, but the disclosure is not limited thereto. A thickness of the well layer may be in a range of about 1 nm to about 4 nm, and a thickness of the barrier layer may be in a range of about 3 nm to about 10 nm in the thickness direction of the substrate 110.

In another embodiment, the active layer MQW may have a structure in which semiconductor materials having large band gap energy and semiconductor materials having small band gap energy are alternately stacked on top of each other, and may include group III to V semiconductor materials according to a wavelength band of emitted light. The light emitted by the active layer MQW is not limited to the first light, and in an embodiment, a second light (light of a green wavelength band) or a third light (light of a red wavelength band) may be emitted. In an embodiment, in case that the semiconductor materials included in the active layer MQW include indium, a color of the emitted light may vary according to a content of indium. For example, in case that the content of indium is about 15%, light of the blue wavelength band may be emitted, in case that the content of indium is about 25%, light of the green wavelength band may be emitted, and in case that the content of indium is greater than or equal to about 35%, light of the red wavelength band may be emitted.

The second semiconductor layer SEM2 may be disposed on the active layer MQW. The second semiconductor layer SEM2 may be an n-type semiconductor. The second semiconductor layer SEM2 may include a semiconductor material having a chemical formula of AlₓGa_{y}In_{1-x-y}N (0≤x≤1, 0≤y≤1, 0≤x+y≤1). For example, the second semiconductor layer SEM2 may be one or more of n-type doped AlGaInN, GaN, AlGaN, InGaN, AlN, InN, and the like. The second semiconductor layer SEM2 may be doped with an n-type dopant, and the n-type dopant may be Si, Ge, Sn, or the like. For example, the second semiconductor layer SEM2 may be GaN doped with n-type Si. A thickness of the second semiconductor layer SEM2 may be in a range of about 2 μm to about 4 μm in the thickness direction of the substrate 110, but the disclosure is not limited thereto.

The insulating layer INS may surround side surfaces of the light emitting element LE, e.g., outer circumferential surfaces of the light emitting element LE. The insulating layer INS may insulate the light emitting elements LE from other layers. The insulating layer INS may be directly disposed on outer peripheral surfaces of the first semiconductor layer SEM1, the active layer MQW, and the second semiconductor layer SEM2 to surround the first semiconductor layer SEM1, the active layer MQW, and the second semiconductor layer SEM2. In an embodiment, the insulating layer INS may surround the entire outer peripheral surfaces of the first semiconductor layer SEM1, the active layer MQW, and the second semiconductor layer SEM2.

As illustrated in FIG. 8, the insulating layer INS may be disposed to surround the light emitting elements LE. The insulating layer INS may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), and the like. A thickness of the insulating layer INS may be about 0.1 μm in a radial direction of the light emitting element LE, but the disclosure is not limited thereto.

The display device 10 according to an embodiment may include a first capping layer CAP1 and a first reflective layer RFL1 disposed on each of the pixel electrodes PE1, PE2, and PE3 and surrounding at least a portion of the light emitting elements LE.

The first capping layer CAP1 may be disposed on each of the pixel electrodes PE1, PE2, and PE3 and the bank layer BNL. The first capping layer CAP1 may be disposed to surround a side surface of the light emitting element LE. For example, the first capping layer CAP1 may surround an outer peripheral surface of the light emitting element LE, and may surround side surfaces of the first semiconductor layer SEM1, the active layer MQW, and the second semiconductor layer SEM2 of the light emitting element LE. The first capping layer CAP1 may completely surround the side surfaces of the first semiconductor layer SEM1 and the active layer MQW of the light emitting element LE, and may surround at least a portion of the side surface of the second semiconductor layer SEM2. The first capping layer CAP1 may extend in the third direction DR3 from a top surface of each of the pixel electrodes PE1, PE2, and PE3 to surround the light emitting elements LE, and extend to a height lower than a height of the light emitting element LE in the third direction DR3.

The first capping layer CAP1 may be disposed between the first reflective layer RFL1 and the light emitting element LE to insulate between the first reflective layer RFL1 and the light emitting element LE. For example, the first capping layer CAP1 may separate the first reflective layer RFL1 and the light emitting element LE from each other. The first capping layer CAP1 may directly contact the insulating layer INS of the light emitting element LE.

The first capping layer CAP1 may include an inorganic material. For example, the first capping layer CAP1 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

Although it is illustrated in the drawing that the first capping layer CAP1 may be formed as a single layer, the disclosure is not limited thereto. For example, the first capping layer CAP1 may be formed as a multilayer in which inorganic layers, each of which includes at least one of the inorganic materials that may be included in the first capping layer CAP1, are alternately stacked on top of each other. The thickness of the first capping layer CAP1 may be in a range of about 0.05 μm to about 2 μm in the thickness direction of the substrate 110, but the disclosure is not limited thereto.

The first reflective layer RFL1 may be disposed on the first capping layer CAP1. The first reflective layer RFL1 may directly contact a surface of the first capping layer CAP1. The first reflective layer RFL1 may be disposed to surround the side surface of the light emitting element LE. For example, the first reflective layer RFL1 may surround the outer peripheral surface of the light emitting element LE, and may surround the side surfaces of the first semiconductor layer SEM1, the active layer MQW, and the second semiconductor layer SEM2 of the light emitting element LE. The first reflective layer RFL1 may surround the side surfaces of the first semiconductor layer SEM1 and the active layer MQW of the light emitting element LE, and may surround at least a portion of the side surface of the second semiconductor layer SEM2. The first reflective layer RFL1 may extend in the third direction DR3 from the top surface of each of the pixel electrodes PE1, PE2, and PE3 to surround the light emitting elements LE, and may extend to a height lower than the height of the light emitting element LE in the third direction DR3. The height of the first reflective layer RFL1 and the height of the first capping layer CAP1 may be substantially the same. The height of the first reflective layer RFL1 and the height of the first capping layer CAP1 may be heights from the top surface of the first pixel electrode PE1 to the highest point in the thickness direction of the substrate 110.

The first reflective layer RFL1 may reflect light emitted from the light emitting element LE. For example, the first reflective layer RFL1 may reflect light emitted from the active layer MQW of the light emitting element LE to the side surface, upward (e.g., in the third direction DR3). For example, the first reflective layer RFL1 may improve light output efficiency of the light emitting element LE. The first reflective layer RFL1 may be disposed to surround at least the side surface of the active layer MQW of the light emitting element LE. The height of the first reflective layer RFL1 in contact with the light emitting element LE may be greater than or equal to about 50% of the height of the light emitting element LE. For example, in case that the height of the light emitting element LE is about 10 μm, the first reflective layer RFL1 may have a height of in a range of about 5 μm to about 10 μm. Accordingly, the first reflective layer RFL1 may be disposed to surround entire side surface of the active layer MQW of the light emitting element LE to reflect light emitted from the active layer MQW.

The first reflective layer RFL1 may include a metal having a high reflectance. For example, the first reflective layer RFL1 may include aluminum, silver, the like, or an alloy thereof.

As illustrated in FIG. 9, the first capping layer CAP1 and the first reflective layer RFL1 may correspond to each of the emissions areas EA1, EA2, and EA3 and be disposed to overlap the emission areas EA1, EA2, and EA3 in a plan view. The first capping layer CAP1 and the first reflective layer RFL1 disposed in each of the emission areas EA1, EA2, and EA3 may be disposed to be spaced apart from the first capping layer CAP1 and the first reflective layer RFL1 disposed in the adjacent emission areas EA1, EA2, and EA3. The first capping layer CAP1 and the first reflective layer RFL1 may include multiple holes disposed in areas corresponding to the light emitting elements LE in a plan view. For example, the first capping layer CAP1 and the first reflective layer RFL1 may not be formed in an area corresponding to each of the light emitting elements LE.

The display device 10 according to the embodiment may include the first capping layer CAP1 and the first reflective layer RFL1 surrounding the side surface of the light emitting element LE, so that light emitted from the light emitting element LE to the side surface may be reflected upward. Accordingly, the first capping layer CAP1 and the first reflective layer RFL1 may improve light output efficiency of the light emitting element LE.

The first via layer VIA1 may be disposed on the first reflective layer RFL1. The first via layer VIA1 may prevent components disposed under the first reflective layer RFL1 from being damaged in an etching process of the light emitting element LE, which will be described below. For example, the first via layer VIA1 may protect the first reflective layer RFL1 disposed under the first via layer VIAL The first via layer VIA1 may contact a top surface of the first reflective layer RFL1 and may be disposed to be spaced apart from an edge of the first reflective layer RFL1. For example, the first via layer VIA1 may be disposed only on the first reflective layer RFL1. The first via layer VIA1 may cover the first reflective layer RFL1 and may be formed to have a height (e.g., a predetermined or selectable height). For example, the height of the first via layer VIA1 may be less than the height of the light emitting element LE in the third direction DR3.

The first via layer VIA1 may be disposed to correspond to each of the emission areas EA1, EA2, and EA3. The first via layer VIA1 may be disposed in an island pattern shape in each of the emission areas EA1, EA2, and EA3. For example, the first via layer VIA1 disposed in each of the emission areas EA1, EA2, and EA3 may be disposed to be spaced apart from the first via layer VIA1 disposed in the adjacent emission areas EA1, EA2, and EA3. A planar shape of the first via layer VIA1 may be similar to a planar shape of the first reflective layer RFL1 described above.

The first via layer VIA1 may include an organic material to flatten the stepped portion disposed under the first reflective layer RFL1 or the like. For example, the first via layer VIA1 may include an acrylic resin, an epoxy resin, a phenolic resin, a polyamide resin, a polyimide resin, an unsaturated polyester resin, a polyphenylene resin, a polyphenylenesulfide resin, benzocyclobutene (BCB), or the like.

The second via layer VIA2 may be disposed on the bank layer BNL, the first via layer VIA1, the first reflective layer RFL1, and the first capping layer CAP1. The second via layer VIA2 may cover the first via layer VIA1, the first reflective layer RFL1, and the first capping layer CAP1, and a stepped portion under the bank layer BNL, the first via layer VIA1, the first reflective layer RFL1, and the first capping layer CAP1 may be flattened such that a common electrode CE described below may be formed. The second via layer VIA2 may be formed to have a height (e.g., a predetermined or selectable height) such that at least a portion of the light emitting element LE, for example, the second semiconductor layer SEM2 may protrude above the second via layer VIA2. For example, the height of the second via layer VIA2 may be less than the height of the light emitting element LE in the third direction DR3.

The second via layer VIA2 may cover and protect the first via layer VIA1, the first reflective layer RFL1, and the first capping layer CAP1 disposed in each of the emission areas EA1, EA2, and EA3. The second via layer VIA2 may be disposed to correspond to each of the emission areas EA1, EA2, and EA3. The second via layer VIA2 may be disposed in an island pattern shape in each of the emission areas EA1, EA2, and EA3. For example, the second via layer VIA2 disposed in each of the emission areas EA1, EA2, and EA3 may be disposed to be spaced apart from the second via layer VIA2 disposed in the adjacent emission areas EA1, EA2, and EA3. A planar shape of the second via layer VIA2 may be similar to the planar shape of the first reflective layer RFL1 described above.

The common electrode CE may be disposed on the second via layer VIA2, the bank layer BNL, and the light emitting elements LE. The common electrode CE may be disposed on the substrate 110 on which the light emitting element LE is formed, and may be disposed in an entire area of the display area DPA of the substrate 110. The common electrode CE may be disposed to overlap each of the emission areas EA1, EA2, and EA3 and the non-emission area NEA, and may be formed with a thin thickness such that light may be emitted.

The common electrode CE may be directly disposed on the top surface and the side surface of the light emitting elements LE. The common electrode CE may directly contact the second semiconductor layer SEM2 exposed on the top surface of the light emitting element LE. As illustrated in FIG. 6, the common electrode CE may be a common layer that covers the light emitting elements LE and commonly connects the light emitting elements LE. Since the second semiconductor layer SEM2 having a conductivity has a patterned structure in each of the light emitting elements LE, the common electrode CE may directly contact the second semiconductor layer SEM2 of each of the light emitting elements LE so that a common voltage may be applied to each of the light emitting elements LE.

Since the common electrode CE is entirely disposed on the substrate 110 and a common voltage is applied, the common electrode CE may include a material having a low resistance. The common electrode CE may be formed to have a thin thickness to allow light to pass through the common electrode CE. For example, the common electrode CE may include a metal having a low resistance, such as aluminum (Al), silver (Ag), copper (Cu), or the like, or a metal oxide such as ITO, IZO, ITZO, or the like. A thickness of the common electrode CE may be in a range of about 10 Å to about 200 Å in the thickness direction of the substrate 100, but the disclosure is not limited thereto.

The above-described light emitting elements LE may receive a pixel voltage or an anode voltage from each of the pixel electrodes PE1, PE2, and PE3, and may receive a common voltage through the common electrode CE. The light emitting elements LE may emit light with a luminance according to a voltage difference between the pixel voltage and the common voltage. In an embodiment, by disposing the light emitting elements LE, for example, inorganic light emitting diodes on the pixel electrodes PE1, PE2, and PE3, disadvantages of organic light emitting diodes, which are vulnerable to external moisture or oxygen, may be prevented, and lifespan and reliability may be improved.

As illustrated in FIG. 9, the light emitting elements LE may be disposed on each of the pixel electrodes PE1, PE2, and PE3. The light emitting elements LE may be regularly arranged in a pattern. For example, the light emitting elements LE may be disposed to be spaced apart from each other with regular distance.

The light emitting elements LE may be generally disposed on each of the pixel electrodes PE1, PE2, and PE3. However, the disclosure is not limited thereto, and some light emitting elements LE may be disposed between the pixel electrodes PE1, PE2, and PE3, or may be partially disposed on a pixel electrode PE1, PE2, or PE3, or may not be disposed on any pixel electrode.

The light emitting element part LEP may further include a second capping layer CAP2 covering the common electrode CE. The second capping layer CAP2 may be directly disposed on the common electrode CE. The second capping layer CAP2 may serve to cover elements disposed under the second capping layer CAP2, e.g., the light emitting elements LE and the common electrode CE, to protect the elements from moisture or foreign substances. The second capping layer CAP2 may include an inorganic material. For example, the second capping layer CAP2 and the first capping layer CPA1 may include a same material.

A wavelength controller 200 may be disposed on the light emitting element part LEP. The wavelength controller 200 may include a wavelength conversion layer QDL, a second reflective layer RFL2, a partition wall PWL including a first partition wall PW1 and a second partition wall PW2, and a cover layer TRL.

The partition wall PWL may be disposed on the second capping layer CAP2, and may partition each of the emission areas EA1, EA2, and EA3. The partition wall PWL may extend in the first direction DR1 and the second direction DR2, and may be formed in a grid pattern in the entire display area DPA in a plan view. Further, the partition wall PWL may not overlap the emission areas EA1, EA2, and EA3, and may overlap the non-emission area NEA in a plan view.

The partition wall PWL may serve to provide a space for forming the wavelength conversion layer QDL. The partition wall PWL may include the first partition wall PW1 and the second partition wall PW2 disposed on the first partition wall PW1. In order to provide a space for forming the wavelength conversion layer QDL, the partition wall PWL may have a two-layer structure including the first partition wall PW1 and the second partition wall PW2 to have a large thickness. For example, a thickness of the first partition wall PW1 and a thickness of the second partition wall PW2 may be in a range of about 1 μm to about 10 μm. The first partition wall PW1 and the second partition wall PW2 may include an organic insulating material to have a large thickness. The organic insulating material may include, for example, an epoxy resin, an acrylic resin, a cardo resin, an imide resin, or the like.

In an embodiment, the first partition wall PW1 and the second partition wall PW2 may block transmission of light in the non-emission area NEA. The first partition wall PW1 and the second partition wall PW2 may further include a light blocking material, and may include a dye or pigment having a light blocking property. For example, the first partition wall PW1 and the second partition wall PW2 may be a black matrix. External light incident from an outside of the display device 10 may cause a problem that color reproducibility of the wavelength controller 200 is distorted. In accordance with the embodiment, at least a portion of the external light may be absorbed by the light blocking material by disposing the partition wall PWL including the light blocking material in the wavelength controller 200. Accordingly, color distortion caused by the reflection of the external light may be reduced. Further, the partition wall PWL including the light blocking material may prevent light infiltration and color mixture between adjacent emission areas, which leads to further improvement of color reproducibility. In the embodiment, although the partition wall PWL including the first partition wall PW1 and the second partition wall PW2 has been illustrated and described, the disclosure is not limited thereto, and the partition wall PWL may be formed of a single layer.

The second reflective layer RFL2 may be disposed on the partition wall PWL. The second reflective layer RFL2 may not overlap the emission areas EA1, EA2, and EA3 and may be disposed to overlap the non-emission area NEA in a plan view. The second reflective layer RFL2 may extend in the first direction DR1 and the second direction DR2, and may be formed in a grid pattern in the entire display area DPA in a plan view. The second reflective layer RFL2 may entirely overlap the partition wall PWL in a plan view.

The second reflective layer RFL2 may reflect light emitted from the light emitting elements LE upward (e.g., in the third direction DR3). The second reflective layer RFL2 may include a metal having a high light reflectance. The second reflective layer RFL2 and the first reflective layer RFL1 may include a same material.

The cover layer TRL may be disposed on the second reflective layer RFL2. The cover layer TRL may overlap a portion of the emission areas EA1, EA2, and EA3 and the non-emission area NEA in a plan view. The cover layer TRL may extend in the first direction DR1 and the second direction DR2, and may be formed in a grid pattern in the entire display area DPA in a plan view.

The cover layer TRL may cover the partition wall PWL and the second reflective layer RFL2. The cover layer TRL may include a light transmitting organic material so that light reflected from the second reflective layer RFL2 may be emitted upward. For example, the cover layer TRL may include an epoxy resin, an acrylic resin, a cardo resin, an imide resin, or the like.

The wavelength conversion layer QDL may be disposed in each of the emission areas EA1, EA2, and EA3. The wavelength conversion layer QDL may emit light by converting or shifting a peak wavelength of incident light to another peak wavelength (e.g., another specific peak wavelength). The wavelength conversion layer QDL may convert the first light that is blue light emitted from the light emitting element LE into the second light that is red light or into the third light that is green light, or may transmit the first light that is blue light without conversion.

The wavelength conversion layer QDL may be disposed in each of the emission areas EA1, EA2, and EA3 partitioned by the partition wall PWL, and may be spaced apart from each other. For example, the wavelength conversion layer QDL may have island patterns spaced apart from each other. The wavelength conversion layer QDL may be disposed in each of the first emission area EA1, the second emission area EA2, and the third emission area EA3. In an embodiment, each of the wavelength conversion layers QDL may completely overlap the first emission area EA1, the second emission area EA2, and the third emission area EA3 in a plan view.

The wavelength conversion layer QDL may include a first wavelength conversion pattern WCL1 in the first emission area EA1, a second wavelength conversion pattern WCL2 in the second emission area EA2, and a light transmission pattern TPL in the third emission area EA3.

The first wavelength conversion pattern WCL1 may overlap the first emission area EA1 in a plan view. The first wavelength conversion pattern WCL1 may emit light by converting or shifting the peak wavelength of incident light to another specific peak wavelength. In an embodiment, the first wavelength conversion pattern WCL1 may convert the first light that is blue light emitted from the light emitting element LE of the first emission area EA1 into the second light that is red light having a peak wavelength in a range of about 610 nm to about 650 nm and emit the red light.

The first wavelength conversion pattern WCL1 may include a first base resin BRS1, a first wavelength conversion particle WCP1, and a scatterer SCP. The first base resin BRS1 may include a light-transmissive organic material. For example, the first base resin BRS1 may include an epoxy resin, an acrylic resin, a cardo resin, an imide resin, or the like.

The first wavelength conversion particle WCP1 may convert the first light incident from the light emitting element LE into second light. For example, the first wavelength conversion particle WCP1 may convert light in a blue wavelength band into light in a red wavelength band. The first wavelength conversion particle WCP1 may be a quantum dot (QD), a quantum rod, a fluorescent material, a phosphorescent material, or the like. For example, a quantum dot may be a particulate material that emits light of a specific color in case that an electron transitions from a conduction band to a valence band.

The quantum dot may be a semiconductor nanocrystal material. The quantum dot may have a specific band gap according to a composition and a size of the quantum dot. Thus, the quantum dot may absorb light and emit light having an intrinsic wavelength. Examples of semiconductor nanocrystal of quantum dots may include group IV element, group IV compound, group II-VI compound, group III-V compound, group IV-VI compound, the like, or a combination thereof.

The group II-VI compound may be selected from the group consisting of binary compounds, ternary compounds, and quaternary compounds, wherein the binary compounds may be selected from the group consisting of CdSe, CdTe, ZnS, ZnSe, ZnTe, ZnO, HgS, HgSe, HgTe, MgSe, MgS, and mixtures thereof, the ternary compounds may be selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and the quaternary compounds may be selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group III-V compound may be selected from the group consisting of binary compounds, ternary compounds, and quaternary compounds, wherein the binary compounds may be selected from the group consisting of GaN, GaP, GaAs, GaSb, AlN, AlP, AlAs, AlSb, InN, InP, InAs, InSb, and mixtures thereof, the ternary compounds may be selected from the group consisting of GaNP, GaNAs, GaNSb, GaPAs, GaPSb, AlNP, AINAs, AlNSb, AlPAs, AlPSb, InGaP, InNP, InAlP, InNAs, InNSb, InPAs, InPSb, GaAlNP, and mixtures thereof, and the quaternary compounds may be selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The group IV-VI compound may be selected from the group consisting of binary compounds, ternary compounds, and quaternary compounds, wherein the binary compounds may be selected from the group consisting of SnS, SnSe, SnTe, PbS, PbSe, PbTe, and mixtures thereof, the ternary compounds may be selected from the group consisting of SnSeS, SnSeTe, SnSTe, PbSeS, PbSeTe, PbSTe, SnPbS, SnPbSe, SnPbTe, and mixtures thereof, and the quaternary compounds may be selected from the group consisting of SnPbSSe, SnPbSeTe, SnPbSTe, and mixtures thereof. The group IV element may be selected from the group consisting of Si, Ge, and mixtures thereof. The group IV compound may be a binary compound selected from the group consisting of SiC, SiGe, and mixtures thereof.

The binary compound, the ternary compound, or the quaternary compound may exist in particles at a uniform concentration, or may exist in particles divided into states where concentration distributions are partially different. Further, the particles may have a core and shell structure in which a quantum dot surrounds another quantum dot. An interface between the core and the shell may have a concentration gradient in which a concentration of elements in the shell decreases toward a center.

In an embodiment, the quantum dot may have a core and shell structure including a core including a nanocrystal (e.g., the semiconductor nanocrystal material described above) and a shell surrounding the core. The shell of the quantum dot may serve as a protective layer for maintaining semiconductor characteristics by preventing chemical denaturation of the core and/or as a charging layer for giving electrophoretic characteristics to the quantum dot. The shell may be a single layer or a multilayer. Examples of the shell of the quantum dot may include a metal or non-metal oxide, a semiconductor compound, the like, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and the like, or a ternary compound such as MgAl₂O₄, CoFe₂O₄, NiFe₂O₄, CoMn₂O₄, and the like, but the disclosure is not limited thereto.

The semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the disclosure is not limited thereto.

The scatterer SCP may scatter light of the light emitting element LE in random directions. The scatterer SCP may have a refractive index different from a refractive index of the first base resin BRS1 and form an optical interface with the first base resin BRS1. For example, the scatterer SCP may be light scattering particles. The scatterer SCP is not particularly limited as long as it is a material capable of scattering at least a portion of the transmitted light, and may be, for example, metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), or the like. Examples of a material of the organic particles may include an acrylic resin, an urethane resin, the like, or a combination thereof. The scatterer SCP may scatter light in random directions regardless of an incidence direction of the incident light without substantially converting a wavelength of the light.

The second wavelength conversion pattern WCL2 may be disposed to overlap the second emission area EA2. The second wavelength conversion pattern WCL2 may emit light by converting or shifting the peak wavelength of incident light to another specific peak wavelength. In an embodiment, the second wavelength conversion pattern WCL2 may convert the first light that is blue light emitted from the light emitting element LE of the second emission area EA2 into the third light that is green light having a peak wavelength in a range of about 510 nm to about 550 nm and emit the green light.

The second wavelength conversion pattern WCL2 may include a second base resin BRS2, a second wavelength conversion particle WCP2, and a scatterer SCP dispersed in the second base resin BRS2.

The second base resin BRS2 may be made of a material having a high light transmittance. In an embodiment, the second base resin BRS2 and the first base resin BRS1 may be made of a same material. In an embodiment, the second base resin BRS2 may include at least one of the materials that can be included in the first base resin BRS1.

The second wavelength conversion particle WCP2 may convert or shift the peak wavelength of incident light to another specific peak wavelength. In an embodiment, the second wavelength conversion particle WCP2 may convert the first light that is blue light provided from the light emitting element LE into the third light that is green light having a peak wavelength in a range of about 510 nm to about 550 nm and emit the green light. Examples of the second wavelength conversion particle WCP2 may include a quantum dot, a quantum rod, a fluorescent material, a phosphorescent material, or the like. A description of the second wavelength conversion particle WCP2 and the description of the first wavelength conversion particle WCP1 may be substantially the same or similar, and thus will be omitted.

The light transmission pattern TPL may be disposed to overlap the third emission area EA3. The light transmission pattern TPL may transmit incident light. The light transmission pattern TPL may transmit the first light that is blue light emitted from the light emitting element LE disposed in the third emission area EA3 without conversion. The light transmission pattern TPL may include a third base resin BRS3 and the scatterer SCP dispersed in the third base resin BRS3. Since the third base resin BRS3 and the first base resin BRS1 are substantially the same or similar, a description thereof will be omitted.

The first light, the second light, and the third light emitted from the above-described wavelength controller 200 may pass through the color filter layer CFL to be described below to display a full color image.

The wavelength controller 200 may further include a third capping layer CAP3 disposed on the cover layer TRL and the wavelength conversion layer QDL. The third capping layer CAP3 may serve to cover the wavelength conversion layer QDL disposed under the third capping layer CAP3 and protect the wavelength conversion layer QDL from moisture or foreign substances. The third capping layer CAP3 may include an inorganic material. A material of the third capping layer CAP3 and the material of the first capping layer CAP1 may be substantially the same or similar.

The color filter layer CFL may be disposed on the wavelength controller 200. The color filter layer CFL may include a first overcoat layer OC1, a first color filter CF1, a second color filter CF2, a third color filter CF3, and a second overcoat layer OC2.

The first overcoat layer OC1 may be disposed on the wavelength controller 200. The first overcoat layer OC1 may be directly disposed on the third capping layer CAP3 of the wavelength controller 200. The first overcoat layer OC1 may be disposed in an entire area of the display area DPA, and may have a flat surface. The first overcoat layer OC1 may flatten the stepped portion formed under the first overcoat layer OC1 by the wavelength controller 200 to facilitate the formation of the color filter layer CFL.

The first overcoat layer OC1 may include a light transmitting organic material. For example, the first overcoat layer OC1 may include an epoxy resin, an acrylic resin, a cardo resin, an imide resin, or the like.

The first color filter CF1, the second color filter CF2, and the third color filter CF3 may be disposed on the first overcoat layer OC1. The first color filter CF1 may be disposed in the first emission area EA1, the second color filter CF2 may be disposed in the second emission area EA2, and the third color filter CF3 may be disposed in the third emission area EA3.

The first color filter CF1, the second color filter CF2, and the third color filter CF3 may include a colorant such as a dye or pigment that absorbs a wavelength other than a corresponding color wavelength. The first color filter CF1 may selectively transmit the second light (e.g., red light), and block or absorb the first light (e.g., blue light) and the third light (e.g., green light). The second color filter CF2 may selectively transmit the third light (e.g., green light), and block or absorb the first light (e.g., blue light) and the second light (e.g., red light). The third color filter CF3 may selectively transmit the first light (e.g., blue light), and block or absorb the second light (e.g., red light) and the third light (e.g., green light). For example, the first color filter CF1 may be a red color filter, the second color filter CF2 may be a green color filter, and the third color filter CF3 may be a blue color filter.

In an embodiment, the light incident on the first color filter CF1 may be the second light converted by the first wavelength conversion pattern WCL1, the light incident on the second color filter CF2 may be the third light converted by the second wavelength conversion pattern WCL2, and the light incident on the third color filter CF3 may be the first light that has passed through the light transmission pattern TPL. As a result, the second light having passed through the first color filter CF1, the third light having passed through the second color filter CF2, and the first light having passed through the third color filter CF3 may be emitted upward from the substrate SUB to display a full color image.

The first color filter CF1, the second color filter CF2, and the third color filter CF3 may absorb a portion of the light coming from the outside of the display device 10 to reduce the reflected light of the external light. Accordingly, the first color filter CF1, the second color filter CF2, and the third color filter CF3 may prevent color distortion caused by the reflection of the external light.

As illustrated in FIG. 10, a planar area of each of the first color filter CF1, the second color filter CF2, and the third color filter CF3 may be greater than a planar area of each of the emission areas EA1, EA2, and EA3. For example, the first color filter CF1 may have a greater planar area than the first emission area EA1. The second color filter CF2 may have a greater planar area than the second emission area EA2. The third color filter CF3 may have a greater planar area than the third emission area EA3. However, the disclosure is not limited thereto, and the planar area of each of the first color filter CF1, the second color filter CF2, and the third color filter CF3 and the planar area of each of the emission areas EA1, EA2, and EA3 may be the same.

The second overcoat layer OC2 may be disposed on the color filter layer CFL. The second overcoat layer OC2 may be directly disposed on the color filter layer CFL. The second overcoat layer OC2 may be disposed in an entire area of the display area DPA, and may have a flat surface. The second overcoat layer OC2 may flatten the stepped portion formed by the lower color filter layer CFL disposed under the second overcoat layer OC2. The second overcoat layer OC2 may include a light transmitting organic material. A material of the second overcoat layer OC2 and the material of the first overcoat layer OC1 may be substantially the same or similar.

As described above, the display device 10 according to an embodiment may form the first reflective layer RFL1 surrounding each of the light emitting elements LE, so that the light emitted from the light emitting element LE to the side surface may be reflected upward. Accordingly, the first reflective layer RFL1 may improve light output efficiency of the light emitting element LE.

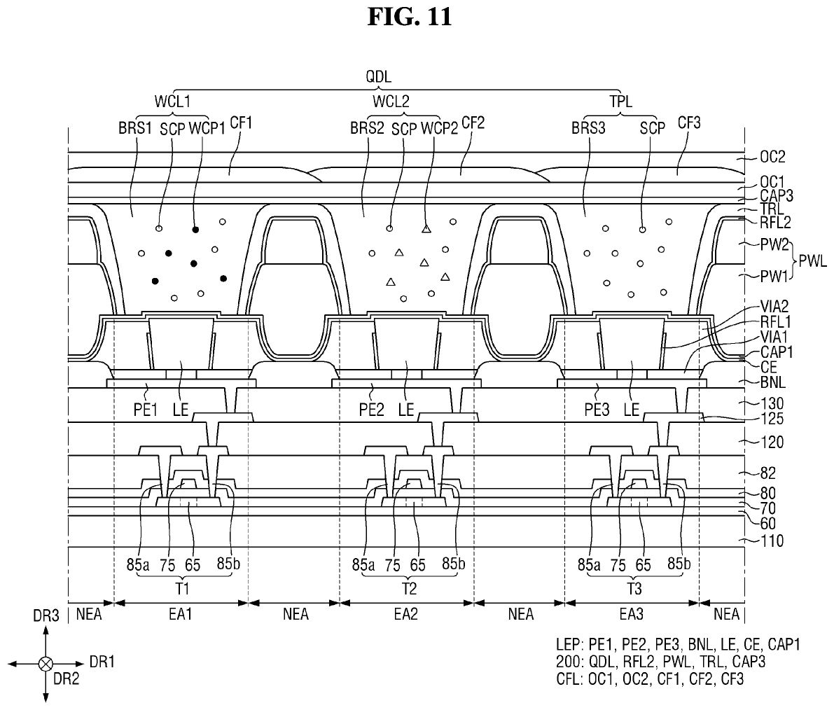

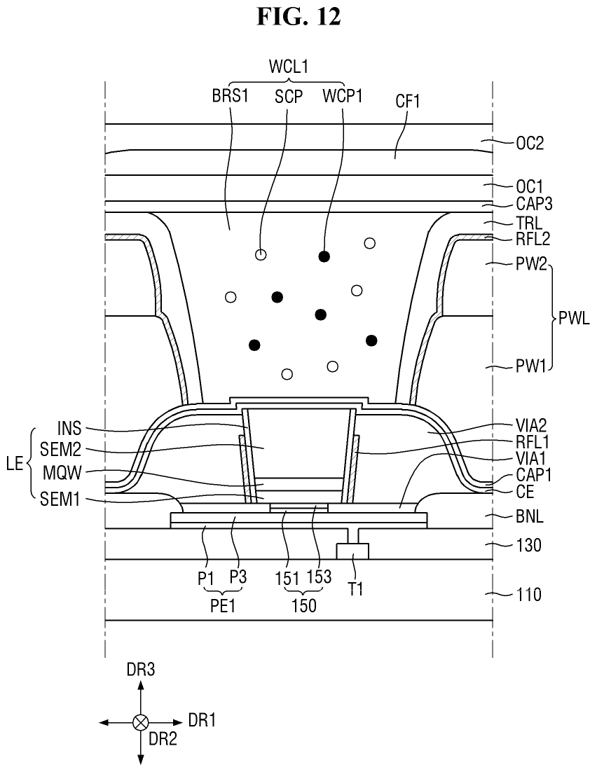

FIG. 11 is a schematic cross-sectional view illustrating a display device according to another embodiment. FIG. 12 is a schematic enlarged view illustrating a first emission area according to another embodiment.

Referring to FIGS. 11 and 12, there is a difference from the embodiment of FIGS. 6 to 10 described above in that the first reflective layer RFL1 surrounding the light emitting element LE may be disposed on the first via layer VIA1. In the following description, redundant description of the above-described embodiments will be omitted while focusing on differences.

The first via layer VIA1 may be disposed on each of the pixel electrodes PE1, PE2, and PE3. The first via layer VIA1 may contact the side surface of the bank layer BNL while covering each of the pixel electrodes PE1, PE2, and PE3. The height of the first via layer VIA1 and the height of the connection electrode 150 of the light emitting LE may be the same. For example, the height of the first via layer VIA1 measured from the top surface of the first pixel electrode PE1 and the height of the connection electrode 150 may be the same. The top surface of the first via layer VIA1 may contact the bottom surface of the first semiconductor layer SEM1 of the light emitting element LE. For example, the top surface of the first via layer VIA1 and the bottom surface of the first semiconductor layer SEM1 of the light emitting element LE may be coplanar with each other. For example, the top surface of the first via layer VIA1 and the bottom surface of the first semiconductor layer SEM1 of the light emitting element LE contact each other. Accordingly, the first reflective layer RFL1 described below may surround the side surfaces of the first semiconductor layer SEM1, the active layer MQW, and the second semiconductor layer SEM2 of the light emitting element LE.

The first reflective layer RFL1 may be disposed on the first via layer VIAL The first reflective layer RFL1 may extend from the top surface of the first via layer VIA1 in the third direction DR3 while surrounding the side surface of the light emitting element LE. Unlike the above-described embodiment, the first reflective layer RFL1 may be disposed on the side surface of the light emitting element LE. As in the manufacturing method described below, since the first reflective layer RFL1 is formed on the side surface of the light emitting element LE, a mask process for manufacturing the first reflective layer RFL1 may be omitted. The first reflective layer RFL1 may surround the side surfaces of the first semiconductor layer SEM1, the active layer MQW, and the second semiconductor layer SEM2 of the light emitting element LE. For example, the first reflective layer RFL1 may surround the entire side surfaces of the first semiconductor layer SEM1 and the active layer MQW and may cover a portion of the side surface of the second semiconductor layer SEM2.

The height of the first reflective layer RFL1 in contact with the light emitting element LE may be greater than or equal to about 50% of the height of the light emitting element LE in the third direction DR3. For example, in case that the height of the light emitting element LE is about 10 μm, the first reflective layer RFL1 may have a height of in a range of about 5 μm to about 10 μm. Accordingly, the first reflective layer RFL1 may surround the entire side surface of the active layer MQW of the light emitting element LE to reflect light emitted from the active layer MQW.

As described above, in the display device 10 according to the embodiment, a separate mask process for forming the first reflective layer RFL1 may be omitted by disposing the first reflective layer RFL1 on the side surface of the light emitting element LE. By forming the first reflective layer RFL1 surrounding each of the light emitting elements LE, the light emitted from the light emitting element LE to the side surface may be reflected upward. Accordingly, the first reflective layer RFL1 may improve light output efficiency of the light emitting element LE.

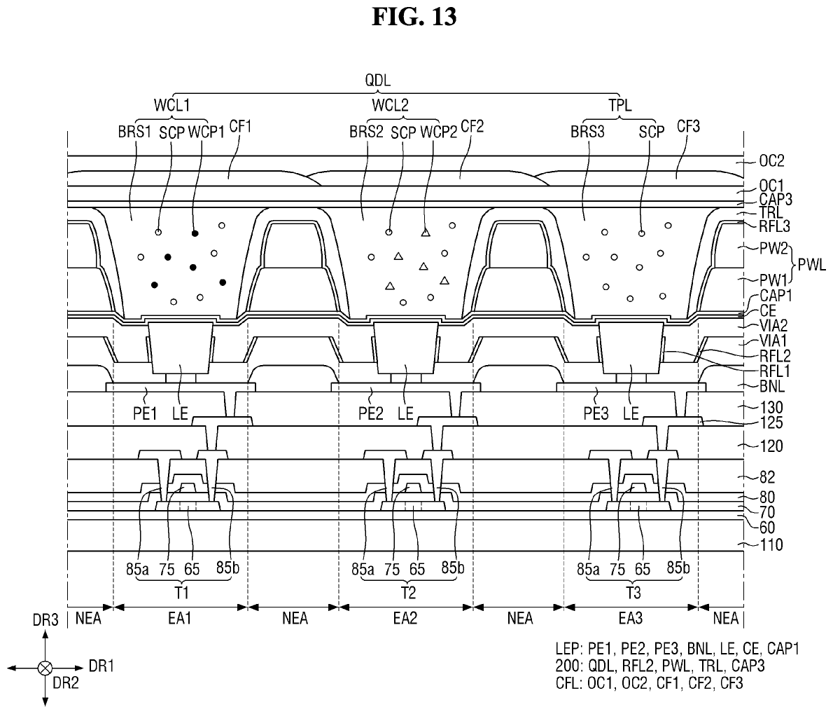

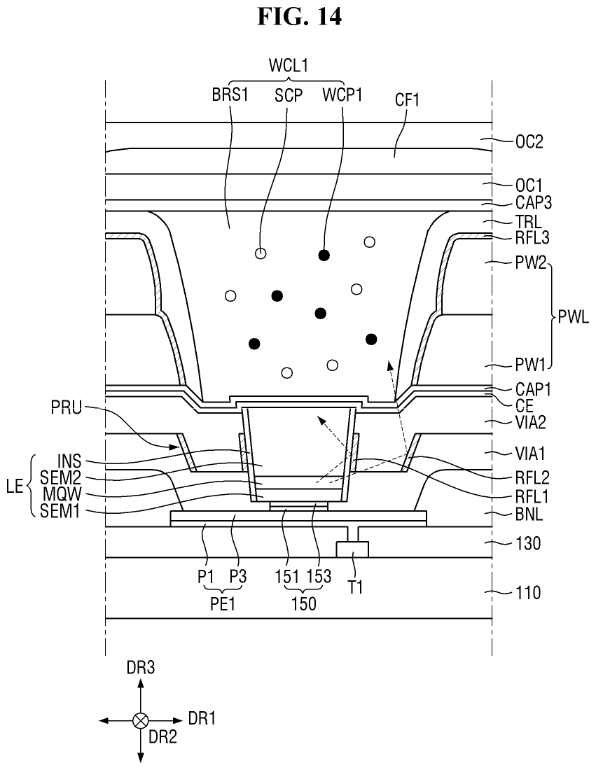

FIG. 13 is a schematic cross-sectional view illustrating a display device according to another embodiment. FIG. 14 is a schematic enlarged view illustrating a first emission area according to another embodiment.

Referring to FIGS. 13 and 14, there is a difference from the above-described embodiments of FIGS. 6 to 12 in that the first reflective layer RFL1 may surround the side surface of the second semiconductor layer SEM2 of the light emitting element LE and the second reflective layer RFL2 spaced apart from the light emitting element LE may be disposed on the first via layer VIA1. In the following description, redundant description of the above-described embodiments will be omitted while focusing on differences.

The first via layer VIA1 may be disposed on the bank layer BNL and each of the pixel electrodes PE1, PE2, and PE3 and may be disposed to cover the bank layer BNL and each of the pixel electrodes PE1, PE2, and PE3. The first via layer VIA1 may further include a protrusion PRU disposed in an area overlapping the bank layer BNL. The protrusion PRU of the first via layer VIA1 may be disposed to surround each of the emission areas EA1, EA2, and EA3 in a plan view. The protrusion PRU may be manufactured by forming the first via layer VIA1 by using a halftone mask as in a manufacturing method described below. The side surface of the protrusion PRU may have a positive tapered shape and may be inclined in a direction parallel to the side surface of the bank layer BNL.

The first via layer VIA1 may be formed to have a height (e.g., a predetermined or selectable height) on the pixel electrodes PE1, PE2, and PE3. For example, the first via layer VIA1 may have at least two heights. The height of the first via layer VIA1 may be greater than the height of the active layer MQW of the light emitting element LE. For example, the first via layer VIA1 may surround the entire side surface of the first semiconductor layer SEM1 and the active layer MQW of the light emitting element LE, and may surround a portion of the side surface of the second semiconductor layer SEM2. For example, the height of the first via layer VIA1 may be greater than the height of the top surface of the active layer MQW of the light emitting element LE. In another embodiment, the height of the first via layer VIA1 and the height of the top surface of the active layer MQW of the light emitting element LE may be same.

The first reflective layer RFL1 may be disposed on the first via layer VIA1 and may surround the side surface of the light emitting element LE. The first reflective layer RFL1 may surround at least a portion of the side surface of the second semiconductor layer SEM2 of the light emitting element LE. The first reflective layer RFL1 may not overlap the first semiconductor layer SEM1 and the active layer MQW of the light emitting element LE in the first direction DR1. The height of the bottom surface of the first reflective layer RFL1 may be greater than the height of the top surface of the active layer MQW of the light emitting element LE. The first reflective layer RFL1 may be disposed to surround the light emitting element LE in a plan view and may have a closed loop shape in a plan view.

In an embodiment, a second reflective layer RFL2 disposed on the side surface of the first via layer VIA1 may be further included. The second reflective layer RFL2 may be disposed on the protrusion PRU of the first via layer VIA1, for example, the second reflective layer RFL2 may be disposed on the side surface of the protrusion PRU. The second reflective layer RFL2 may be disposed to surround the light emitting element LE in a plan view and may have a closed loop shape in a plan view. The second reflective layer RFL2 may be disposed on the side surface of the protrusion PRU having an inclination (e.g., a predetermined or selectable inclination), and may have an inclination (e.g., a predetermined or selectable inclination).

The second reflective layer RFL2 may not overlap the first semiconductor layer SEM1 and the active layer MQW of the light emitting element LE in a horizontal direction (e.g., in the first direction DR1). The height of the bottom surface of the second reflective layer RFL2 may be greater than the height of the top surface of the active layer MQW of the light emitting element LE.

In case that light is emitted from the active layer MQW of the light emitting element LE, some of the light may be reflected by the first reflective layer RFL1 and travel upward. Some other light emitted from the active layer MQW may travel to the first via layer VIA1 through the side surface and be reflected from the second reflective layer RFL2 to travel upward. For example, in the embodiment, in case that the first reflective layer RFL1 is disposed higher than the active layer MQW, light traveling to the side surface of the active layer MQW may be reflected by the second reflective layer RFL2. Accordingly, light output efficiency of the light emitting element LE may be improved.

Hereinafter, a manufacturing process of the display device 10 according to an embodiment will be described with reference to other drawings.

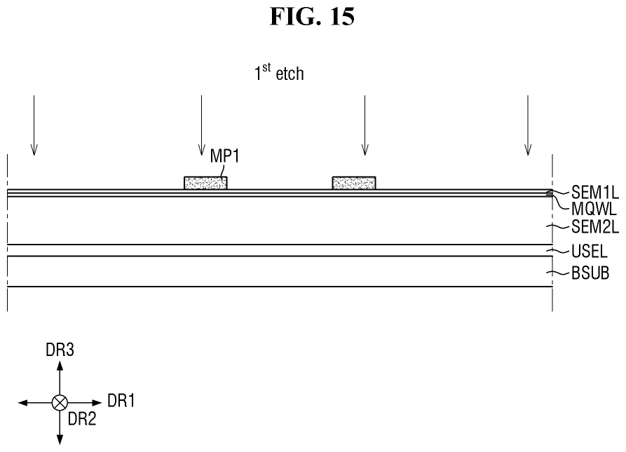

FIGS. 15 to 35 are schematic diagrams illustrating a method of manufacturing a display device according to an embodiment.

FIGS. 15 to 35 are schematic cross-sectional views illustrating structures corresponding to sequence of formation of each of the layers of the display device 10. FIGS. 15 to 35 illustrate manufacturing processes of the light emitting element part LEP, and these may generally each correspond to the schematic cross-sectional views of FIGS. 6 to 8. Further, hereinafter, the first emission area EA1 of the display device 10 will be described.

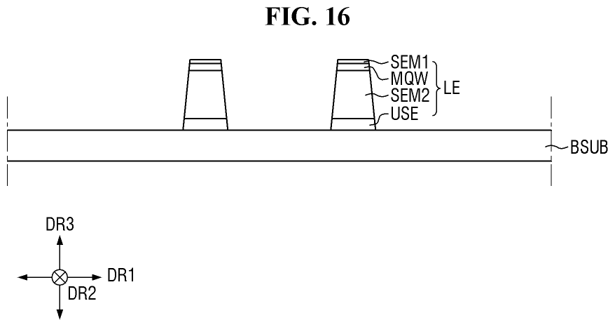

Referring to FIGS. 15 and 16, the light emitting elements LE may be formed on a base substrate BSUB.

The base substrate BSUB may be prepared. The base substrate BSUB may be a sapphire substrate (Al₂O₃), a silicon wafer containing substrate, or the like. However, the disclosure is not limited thereto, and in an embodiment, a case in which the base substrate B SUB is a sapphire substrate will be described as an embodiment.

Multiple semiconductor material layers USEL, SEM2L, MQML, and SEM1L may be formed on the base substrate BSUB. The semiconductor material layers USEL, SEM2L, MQML, and SEM1L grown by an epitaxial method may be formed by growing seed crystals. Here, the semiconductor material layers USEL, SEM2L, MQML, and SEM1L may be formed using one of electron beam deposition, physical vapor deposition (PVD), chemical vapor deposition (CVD), plasma laser deposition (PLD), dual-type thermal evaporation, sputtering, metal organic chemical vapor deposition (MOCVD), or the like. In an embodiment, the semiconductor material layers USEL, SEM2L, MQML, and SEM1L may be formed using the metal organic chemical vapor deposition (MOCVD). However, the disclosure is not limited thereto.

A precursor material for forming the semiconductor material layers may be selected to form a target material in a selectable range without any limitation. For example, the precursor material may be a metal precursor including an alkyl group such as a methyl group, an ethyl group, or the like. Examples of the precursor material may include, but are not limited to, trimethylgallium Ga(CH₃)₃, trimethylaluminum Al(CH₃)₃, triethyl phosphate (C₂H₅)₃PO₄, the like, or a combination thereof.

A third semiconductor material layer USEL may be formed on the base substrate BSUB. Although the drawing illustrates that the third semiconductor material layer USEL may be stacked in a layer, the disclosure is not limited thereto, and multiple layers may be formed. The third semiconductor material layer USEL may be disposed to reduce a lattice constant difference between the second semiconductor material layer SEM2L and the base substrate BSUB. For example, the third semiconductor material layer USEL may include an undoped semiconductor, and may include a material that is not n-type or p-type doped. In an embodiment, the third semiconductor material layer USEL may include, but is not limited to, at least one of undoped InAlGaN, GaN, AlGaN, InGaN, AlN, and InN.

The second semiconductor material layer SEM2L, the active material layer MQWL, and the first semiconductor material layer SEM1L may be sequentially formed on the third semiconductor material layer USEL by using the above-described method.

The semiconductor material layers USEL, SEM2L, MQML, and SEM1L may be etched to form the light emitting elements LE.

Multiple first mask patterns MP1 may be formed on the first semiconductor material layer SEM1L. The first mask pattern MP1 may be a hard mask including an inorganic material or the like, or a photoresist mask including an organic material or the like. The first mask pattern MP1 may prevent the semiconductor material layers USEL, SEM2L, MQML, and SEM1L disposed below the first mask pattern MP1 from being etched. The light emitting elements LE may be formed by partially etching (Pt etch) the semiconductor material layers using the first mask patterns MP1 as a mask.

As illustrated in FIG. 16, the semiconductor material layers USEL, SEM2L, MQML, and SEM1L that do not overlap the first mask pattern MP1 may be etched and removed from the base substrate BSUB, and a portion that is not etched by overlapping with the first mask pattern MP1 may be formed to be light emitting elements LE.

The semiconductor material layers may be etched by a conventional method. For example, a process of etching the semiconductor material layers may be performed by a dry etching method, a wet etching method, a reactive ion etching (RIE) method, a deep reactive ion etching (DRIE) method, an inductively coupled plasma reactive ion etching (ICP-RIE) method, or the like. The dry etching method may be used for vertical etching because anisotropic etching may be performed. In the case of using the etching method, it may be possible to use Cl₂, O₂, or the like as an etchant. However, the disclosure is not limited thereto.

The semiconductor material layers USEL, SEM2L, MQML, and SEM1L overlapping the first mask pattern MP1 may not be etched and be formed the light emitting elements LE. Accordingly, the light emitting elements LE may be formed by including a third semiconductor layer USE, a second semiconductor layer SEM2, an active layer MQW, and a first semiconductor layer SEM1.

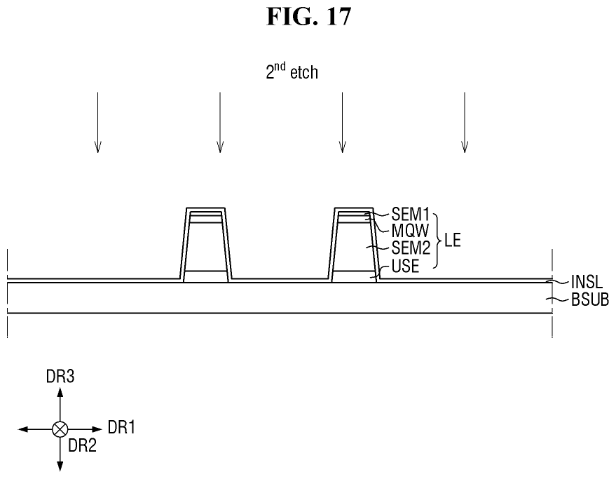

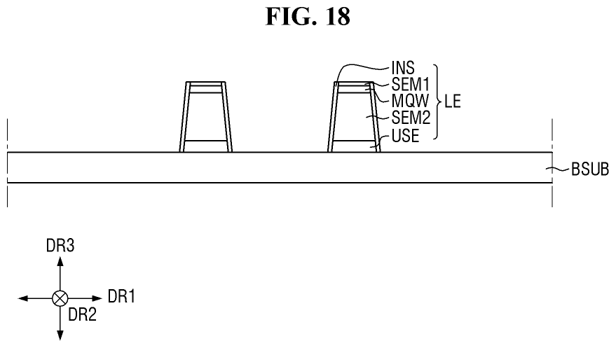

Referring to FIGS. 17 and 18, the insulating layer INS may be formed on the base substrate BSUB on which the light emitting element LE is formed.

The insulating material layer INSL may be formed on outer surfaces of the light emitting elements LE. The insulating material layer INSL may be formed on an entire surface of the base substrate BSUB, and may be formed not only on the light emitting element LE, but also on the top surface of the base substrate BSUB exposed by the light emitting element LE.

A second etching process (2^{nd} etch) that partially removes the insulating material layer INSL may be performed to form the light emitting element LE including the insulating layer INS.

The second etching process (2^{nd} etch) that partially removes a portion of the insulating material layer INSL such that the insulating material layer INSL exposes the top surface of the light emitting element LE but surrounds the side surface of the light emitting element LE, may be performed. In the process, a portion of the insulating material layer INSL may be removed to expose a top surface of the first semiconductor layer SEM1 of the light emitting element LE. The process that partially removes the insulating material layer INSL may be performed by a process such as dry etching that is anisotropic etching, etchback, or the like.

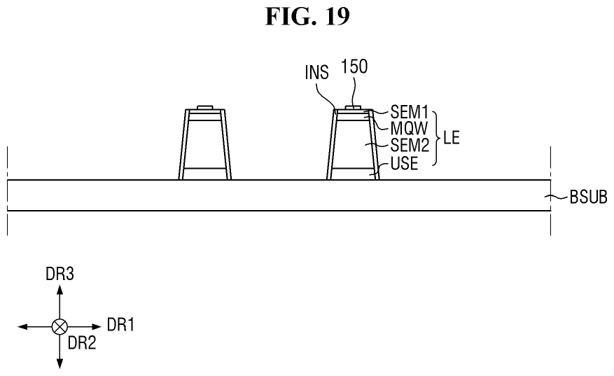

Referring to FIG. 19, the connection electrode 150 may be formed on the first semiconductor layer SEM1 of the light emitting element LE.

The connection electrode 150 may be formed on the first semiconductor layer SEM1 by stacking an electrode material layer on the base substrate BSUB and then etching through an etching process. Although not illustrated, the connection electrode 150 may include the reflective layer 151 (see, e.g., FIG. 8) and the connection layer 153 (see, e.g., FIG. 8).

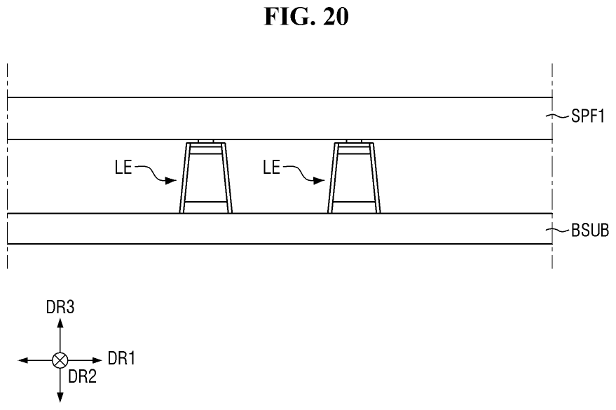

Referring to FIG. 20, a first support film SPF1 may be attached on the light emitting elements LE of the base substrate BSUB manufactured in FIG. 19.

The first support film SPF1 may be attached on the light emitting elements LE. The first support film SPF1 may be aligned on the light emitting elements LE, and may be attached to each connection electrode 150 of the light emitting elements LE. A large number of the light emitting elements LE may be disposed on the base substrate B SUB, and thus the light emitting elements LE may be attached to the first support film SPF1 without being detached.

The first support film SPF1 may include a support layer and an adhesive layer disposed on the support layer. The support layer may be made of a material that is transparent and has mechanical stability to allow light to pass through the support layer. For example, the support layer may include a transparent polymer such as polyester, polyacrylic, polyepoxy, polyethylene, polystyrene, polyethylene terephthalate, or the like. The adhesive layer may include an adhesive material for an adhesion of the light emitting element LE. For example, the adhesive material may include urethane acrylates, epoxy acrylates, polyester acrylates, or the like. The adhesive material may be a material whose adhesive strength changes as ultraviolet (UV), heat, or the like is applied, and thus the adhesive layer may be easily separated from the light emitting element LE.

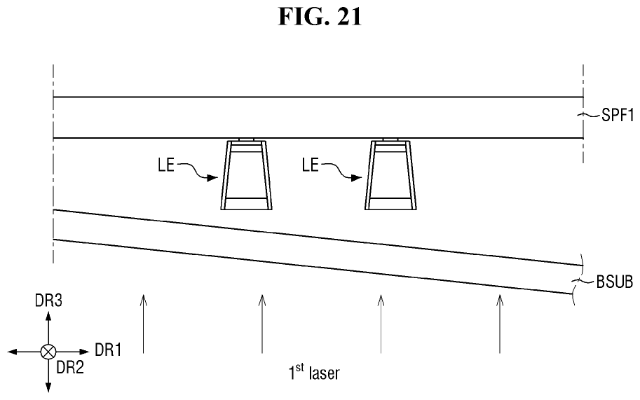

Subsequently, referring to FIG. 21, the light emitting elements LE may be separated from the base substrate BSUB by irradiating the base substrate BSUB with a laser (1^{st} laser). The base substrate BSUB may be separated from each of the third semiconductor layers USE of the light emitting elements LE.

A process of separating the base substrate BSUB may be a laser lift off (LLO) process. In the laser lift off process using laser, KrF excimer laser (about 248 nm wavelength) may be used as a source. An energy density of the excimer laser may be in a range of about 550 mJ/cm² to about 950 mJ/cm², and the incident area may be in a range of about 50×50 μm² to about 1×1 cm², but the disclosure is not limited thereto. By irradiating the laser to the base substrate BSUB, the base substrate BSUB may be separated from the light emitting element LE.

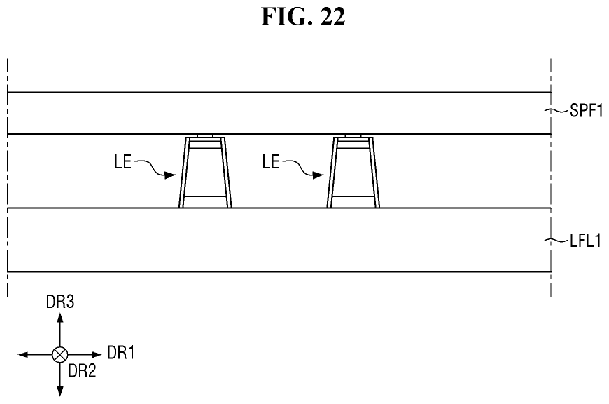

Referring to FIG. 22, the first transfer film LFL1 may be attached to the light emitting elements LE separated from the base substrate BSUB.

The first transfer film LFL1 may be attached on each of the third semiconductor layers USE of the light emitting elements LE. The first transfer film LFL1 may be aligned on the light emitting elements LE and may be attached to each of the third semiconductor layers USE of the light emitting elements LE.

The first transfer film LFL1 may include a stretchable material. The stretchable material may include, e.g., polyolefine, polyvinyl chloride (PVC), elastomeric silicone, elastomeric polyurethane, elastomeric polyisoprene, or the like. Like the above-described first support film SPF1, the first transfer film LFL1 may also include a support layer and an adhesive layer to be attached to and support the light emitting elements LE.

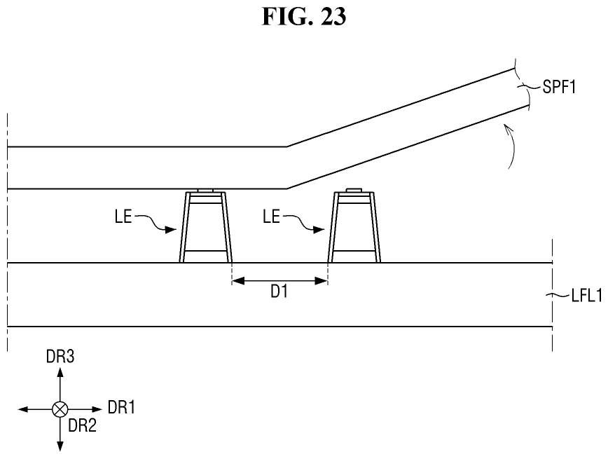

Referring to FIG. 23, the first support film SPF1 may be separated from the light emitting elements LE. After UV or heat is applied to the first support film SPF1 to reduce the adhesive strength of the adhesive layer of the first support film SPF1, the first support film SPF1 may be physically or naturally separated. The light emitting elements LE may be spaced apart from each other by a first interval D1 (e.g., a predetermined or selectable first interval D1) on the first transfer film LFL1 to be arranged in a dot shape.

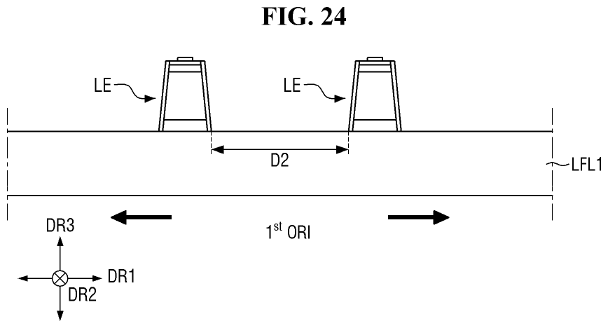

Referring to FIG. 24, the first transfer film LFL1 may be stretched (1^{st} ORI). The first transfer film LFL1 may be stretched two-dimensionally in the first direction DR1 and the second direction DR2. Since the first transfer film LFL1 is stretched, an interval between the light emitting elements LE attached on the first transfer film LFL1 may be a second interval D2 greater than the first interval D1 of FIG. 23. A stretching strength (or tensile strength) of the first transfer film LFL1 may be adjusted according to desired interval of the light emitting elements LE, and may be, for example, about 120 gf/inch. However, the disclosure is not limited thereto.

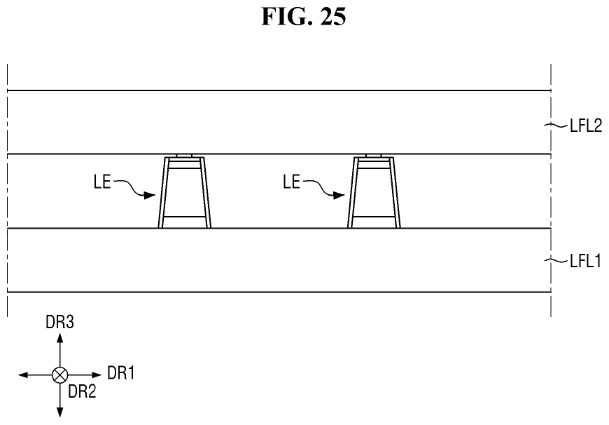

Referring to FIG. 25, a second transfer film LFL2 may be attached on the light emitting elements LE from which the first support film SPF1 is separated. The second transfer film LFL2 may be aligned on the light emitting elements LE, and may be attached on each connection electrode 150 of the light emitting elements LE. The second transfer film LFL2 may include the support layer and the adhesive layer similarly to the above-described first transfer film LFL1 and a detailed description thereof has been made, so that the description thereof will be omitted.

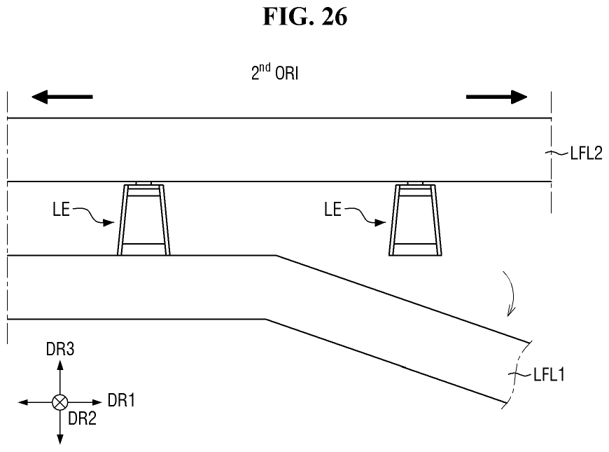

Referring to FIG. 26, the first transfer film LFL1 may be separated from the light emitting elements LE. After UV or heat is applied to the first transfer film LFL1 to reduce the adhesive strength of the adhesive layer of the first transfer film LFL1, the first transfer film LFL1 may be physically or naturally separated.

The second transfer film LFL2 may be stretched (2^{nd} ORI).

The second transfer film LFL2 may be stretched two-dimensionally in the first direction DR1 and the second direction DR2. Since the second transfer film LFL2 is stretched, the interval between the light emitting elements LE attached on the second transfer film LFL2 may be further increased. A stretching strength (or tensile strength) of the second transfer film LFL2 may be adjusted according to the desired interval of the light emitting elements LE, and may be, for example, about 270 gf/inch. However, the disclosure is not limited thereto.

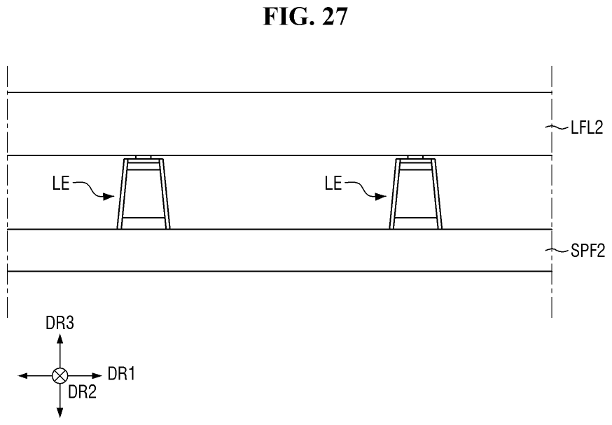

Referring to FIG. 27, a second support film SPF2 may be attached on the light emitting elements LE from which the first transfer film LFL1 is separated. The second support film SPF2 may be aligned on the light emitting elements LE and may be attached to each of the third semiconductor layers USE of the light emitting elements LE. The second support film SPF2 may include the support layer and the adhesive layer similarly to the above-described first support film SPF1 and a detailed description thereof has been made, so that the description thereof will be omitted.

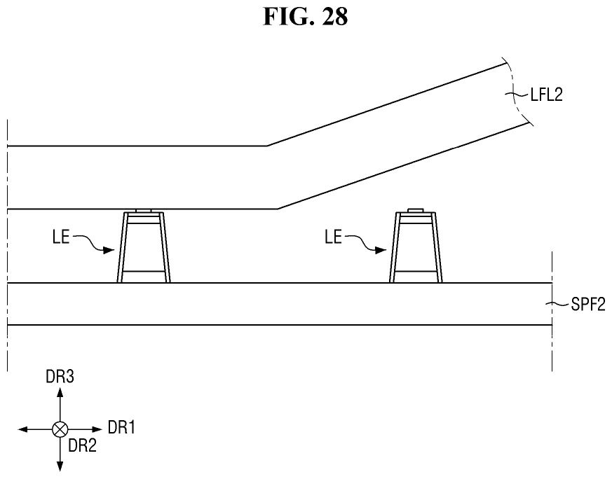

Referring to FIG. 28, the second transfer film LFL2 may be separated. The second transfer film LFL2 attached to the connection electrode 150 of the light emitting elements LE may be separated. Since the separation process of the second transfer film LFL2 and the separation process of the first transfer film LFL1 are the same, the description thereof will be omitted. The second transfer film LFL2 may be separated and removed from the connection electrodes 150 of the light emitting elements LE.

The embodiment has described in which two stretching processes are performed, but the disclosure is not limited thereto. The stretching process may be performed multiple times.

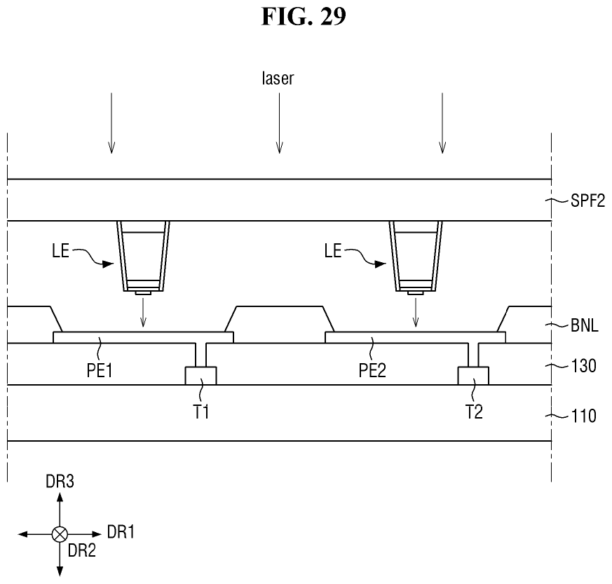

Referring to FIG. 29, the second support film SPF2 may be bonded to the substrate 110 and the light emitting elements LE may be attached on the first and second pixel electrodes PE1 and PE2.

The second support film SPF2 may be aligned on the substrate 110. The connection electrode 150 of the light emitting element LE formed on the second support film SPF2 may be aligned to face the substrate 110. As illustrated in FIG. 6, the substrate 110 may have multiple pixel electrodes PE1, PE2, and PE3, and the bank layer BNL formed on the substrate 110.

The substrate 110 and the second support film SPF2 may be bonded. The connection electrode 150 of the light emitting element LE formed on the second support film SPF2 may be moved to contact the pixel electrodes PE1 and PE2 of the substrate 110. The connection electrode 150 of the light emitting element LE may contact the pixel electrodes PE1 and PE2. The substrate 110 and the second support film SPF2 may be bonded by fusion bonding the connection electrode 150 of the light emitting element LE and the pixel electrodes PE1 and PE2. The light emitting elements LE may be attached to the top surfaces of the pixel electrodes PE1 and PE2.

In the fusion bonding, laser may be irradiated to the pixel electrodes PE1 and PE2 from a position above the second support film SPF2. High heat of the laser may be transferred to the pixel electrodes PE1 and PE2 irradiated with the laser, so that the interfaces between the connection electrode 150 of the light emitting element LE and the pixel electrodes PE1 and PE2 may be attached. The pixel electrodes PE1 and PE2 may include copper (Cu) having excellent heat conduction and may have excellent adhesive properties with respect to the connection electrode 150 of the light emitting element LE. YAG may be used as a source of the laser used for fusion bonding.

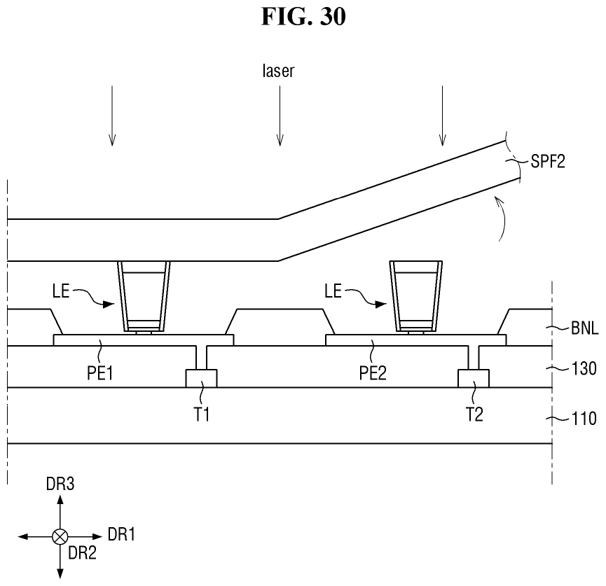

Referring to FIG. 30, the second support film SPF2 may be separated from the light emitting elements LE.

The second support film SPF2 may be separated from the third semiconductor layer USE of the light emitting element LE. The process of separating the second support film SPF2 may be a laser lift off (LLO) process. In the laser lift off process using laser, KrF excimer laser (about 248 nm wavelength) may be used as a source. An energy density of the excimer laser may be in a range of about 550 mJ/cm² to about 950 mJ/cm², and the incident area may be in a range of about 50×50 μm 2 to about 1×1 cm², but the disclosure is not limited thereto. By irradiating the laser to the second support film SPF2, the second support film SPF2 may be separated from the light emitting element LE.

In another embodiment, a process of separating the second support film SPF2 may be a physical separation process other than the laser lift off process. Since the bonding force between the second support film SPF2 and the light emitting element LE is weaker than the bonding force between the connection electrode 150 of the light emitting element LE and the pixel electrodes PE1 and PE2 that are fusion-bonded, the second support film SPF2 may be physically separated because of the difference in the adhesive strength.

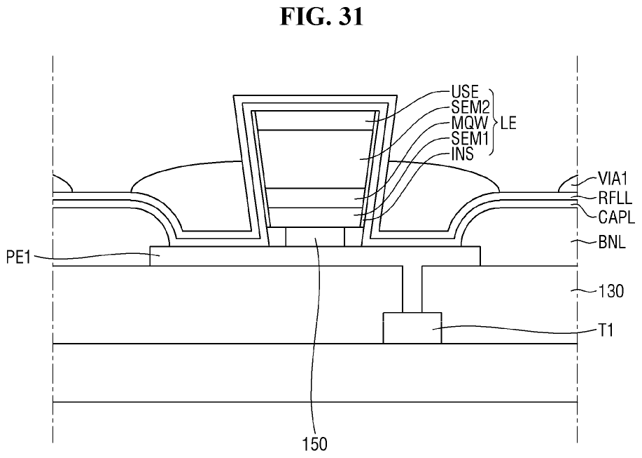

Referring to FIG. 31, a capping material layer CAPL and a reflective material layer RFLL may be sequentially stacked on top of each other on the substrate 110 on which the light emitting elements LE are formed, and the first via layer VIA1 may be formed.

The capping material layer CAPL and the reflective material layer RFLL may be sequentially stacked on top of each other on the substrate 110. The capping material layer CAPL may include an inorganic material and be stacked. The capping material layer CAPL may be stacked on the top surface and side surface of the light emitting element LE and may be extended and stacked on the top surface of the first pixel electrode PE1. The capping material layer CAPL may be stacked to be spaced apart from the connection electrode 150. The reflective material layer RFLL may be stacked on the capping material layer CAPL.

The first via layer VIA1 may be formed on the reflective material layer RFLL. The first via layer VIA1 may be formed on the reflective material layer RFLL, and in each of the emission areas EA1 and EA2, the first via layers VIA1 may be disposed to be spaced apart from each other between adjacent emission areas (e.g., between the first emission area EA1 and the second emission area EA2). The first via layer VIA1 may be formed by applying a solution using a solution process such as spin coating, inkjet printing, or the like and patterned by an exposure process. The first via layer VIA1 may be formed to have a height greater than the height of the active layer MQW of the light emitting element LE.

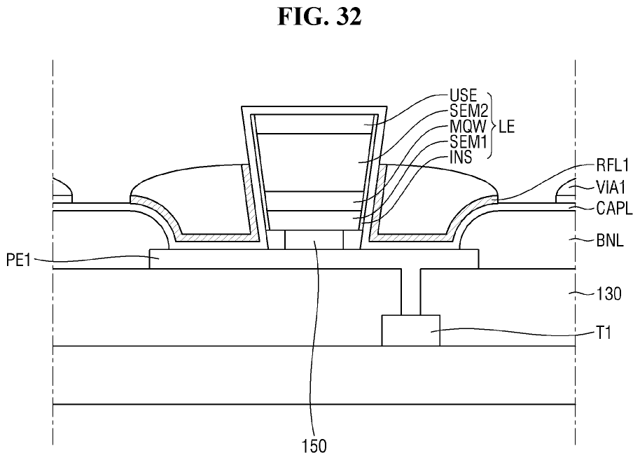

Referring to FIG. 32, the first reflective layer RFL1 may be formed by etching a portion of the reflective material layer RFLL. The reflective material layer RFLL may be etched using the first via layer VIA1 as a mask. The reflective material layer RFLL may be etched using, for example, a wet etching process, but the disclosure is not limited thereto. The first reflective layer RFL1 may be formed to be aligned with the bottom surface and side surface of the first via layer VIAL

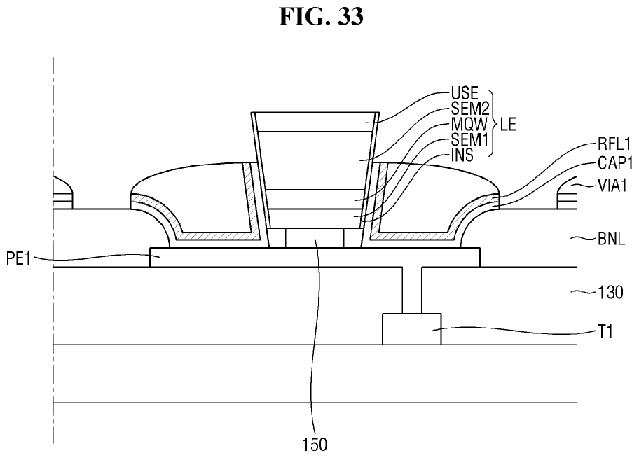

Referring to FIG. 33, the first capping layer CAP1 may be formed by etching the capping material layer CAPL. The capping material layer CAPL may be etched using the first via layer VIA1 as a mask. The capping material layer CAPL may be etched using, for example, a dry etching process, but the disclosure is not limited thereto. Similarly to the first reflective layer RFL1, the first capping layer CAP1 may be formed to be aligned with the bottom surface and side surface of the first via layer VIAL Accordingly, the side surfaces of the first capping layer CAP1 and the first reflective layer RFL1 may be formed to be aligned with each other. The first capping layer CAP1 and the first reflective layer RFL1 may be formed to surround the side surface of the first semiconductor layer SEM1, the active layer MQW, and the second semiconductor layer SEM2 of the light emitting element LE. The first capping layer CAP1 and the first reflective layer RFL1 may be disposed to be spaced apart from each other between adjacent emission areas on each of the emission areas EA1 and EA2.

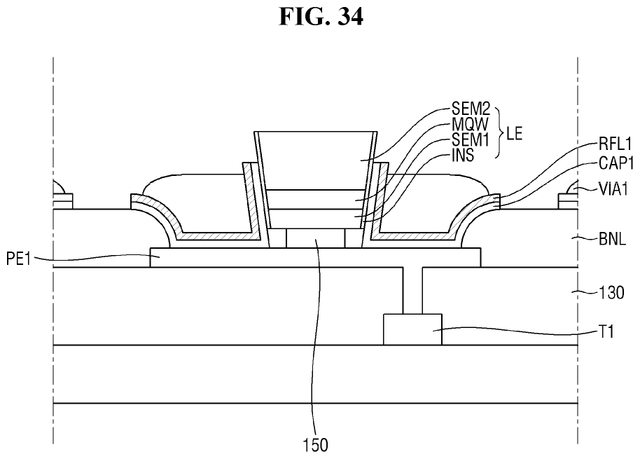

Referring to FIG. 34, a portion of the insulating layer INS of the light emitting element LE and the third semiconductor layer USE may be etched and removed.

The insulating layer INS surrounding the light emitting element LE may be removed using a dry etching process. Only a portion of the insulating layer INS surrounding the third semiconductor layer USE may be removed to expose the third semiconductor layer USE. As the third semiconductor layer USE is exposed, the third semiconductor layer USE may be removed using a dry etching process. Since the third semiconductor layer USE does not have a conductivity, the third semiconductor layer USE may be removed for connection of the common electrode CE. The first via layer VIAL may be partially etched by the above-described dry etching processes, and be formed to be disposed inside the side surfaces of the first reflective layer RFL1 and the first capping layer CAP1.

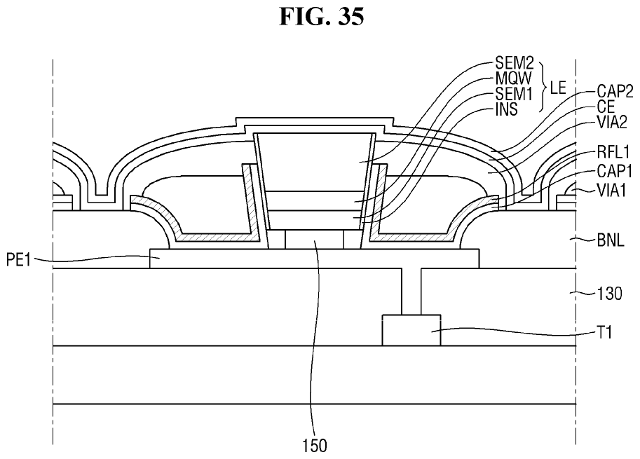

Referring to FIG. 35, the second via layer VIA2, the common electrode CE, and the second capping layer CAP2 may be formed on the first via layer VIAL

The second via layer VIA2 may be formed on the first via layer VIA1, the first reflective layer RFL1, and the bank layer BNL. The second via layer VIA2 and the first via layer VIAL may be manufactured in a same method. The second via layer VIA2 may be disposed to be spaced apart from each other between adjacent emission areas in each of the emission areas EA1 and EA2. The second via layer VIA2 may be formed to have a height less than the height of the second semiconductor layer SEM2 of the light emitting element LE.

The common electrode CE may be formed on the light emitting element LE, the second via layer VIA2, and the bank layer BNL. The common electrode CE may be continuously formed in the entire display area. The common electrode CE may cover the second via layer VIA2, the bank layer BNL, and the light emitting element LE, and may directly contact the second via layer VIA2, the bank layer BNL, and the light emitting element LE. The common electrode CE may be formed by directly contacting the top surface of the second semiconductor layer SEM2 of the light emitting element LE. The second capping layer CAP2 may be formed on the common electrode CE.

As illustrated in FIG. 6, the display device 10 according to an embodiment may be manufactured by forming a partition wall, a wavelength control layer, a color filter layer, and the like.

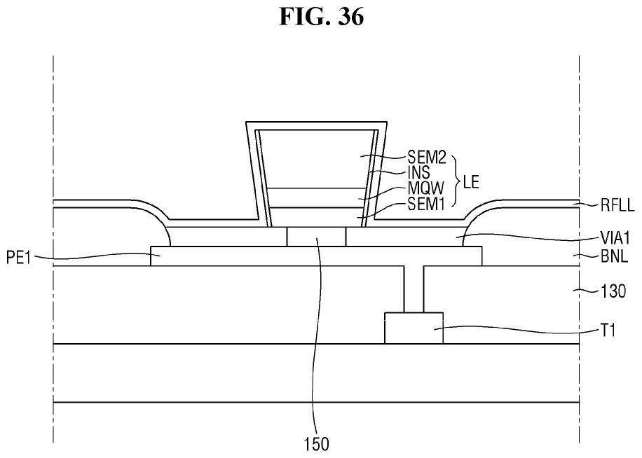

FIGS. 36 to 38 are schematic diagrams illustrating a method of manufacturing a display device according to another embodiment. FIGS. 36 to 38 may substantially each correspond to the schematic cross-sectional views of FIGS. 11 and 12. Since the above-described processes of FIGS. 15 to 30 are the same, subsequent processes will be described.

Referring to FIG. 36, the first via layer VIAL may be formed on the substrate 110 on which the light emitting elements LE are formed, and the third semiconductor layer of the light emitting element LE may be etched, and then the reflective material layer RFLL may be stacked.

The first via layer VIA1 may be formed on the first pixel electrode PE1 partitioned by the bank layer BNL. The first via layer VIA1 may be formed on the first pixel electrode PE1 and may be spaced apart from each other between adjacent emission areas in each of the emission areas EA1 and EA2. The first via layer VIA1 may be formed by applying a solution using a solution process such as spin coating, inkjet printing, or the like and patterned by an exposure process. The first via layer VIA1 and the connection electrode 150 of the light emitting element LE may be formed to have a same height.

A portion of the insulating layer INS surrounding the light emitting element LE may be removed using a dry etching process, and the exposed third semiconductor layer of the light emitting element LE may be removed using a dry etching process.

The reflective material layer RFLL may be formed by forming and stacking a metal on the substrate 110. The reflective material layer RFLL may be stacked on the top surface and side surface of the light emitting element LE and may be extended and stacked on the top surface of the first via layer VIAL

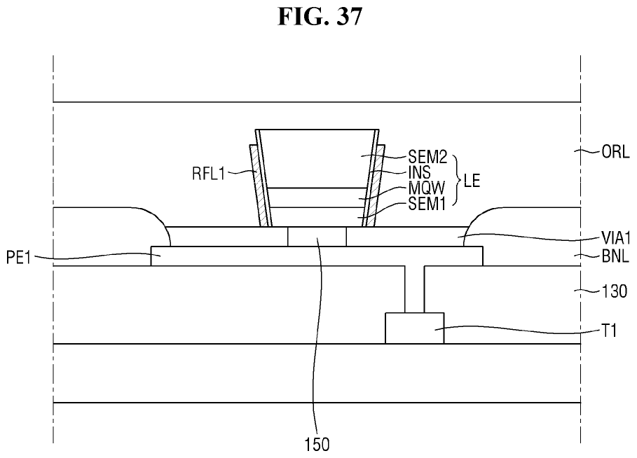

Referring to FIG. 37, the first reflective layer RFL1 may be formed by etching a portion of the reflective material layer RFLL. A process of etching the reflective material layer RFLL may be performed by a process such as dry etching that is anisotropic etching, etchback, or the like. Except for the portion disposed on the side surface of the light emitting element LE, a remaining area of the reflective material layer RFLL may be etched and removed without a mask process. The first reflective layer RFL1 may be formed to surround the side surfaces of the first semiconductor layer SEM1, the active layer MQW, and the second semiconductor layer SEM2 of the light emitting element LE. The height of the first reflective layer RFL1 may be formed to be less than the height of the light emitting element LE in the thickness direction of the substrate 110.

An organic material layer ORL may be formed by applying an organic material on the substrate 110 on which the first reflective layer RFL1 is formed using a solution process such as spin coating, inkjet printing, or the like. The organic material layer ORL may be formed to completely cover the light emitting element LE.

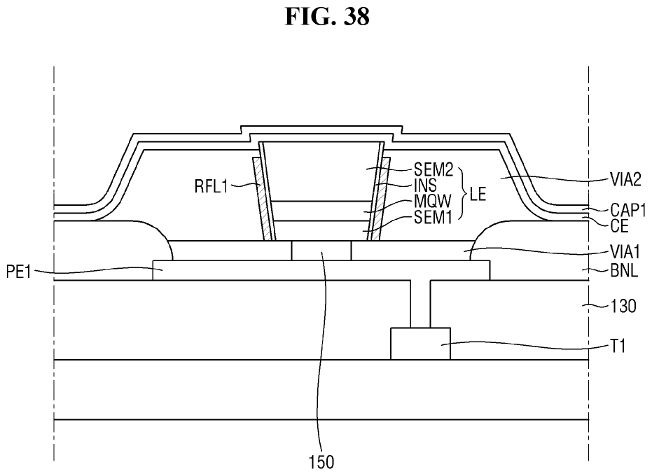

Referring to FIG. 38, the organic material layer ORL may be patterned to form the second via layer VIA2, and the common electrode CE and the first capping layer CAP1 may be sequentially formed on the second via layer VIA2 and the bank layer BNL.

The second via layer VIA2 may be formed on the first via layer VIA1, the first reflective layer RFL1, and the bank layer BNL. The second via layer VIA2 may be patterned through a mask process. The second via layer VIA2 may be disposed to be spaced apart from each other between adjacent emission areas in each of the emission areas EA1 and EA2. The second via layer VIA2 may be formed to have a height less than the height of the second semiconductor layer SEM2 of the light emitting element LE in the thickness direction of the substrate 110.

The common electrode CE and the first capping layer CAP1 may be formed in the same manner as in the above-described embodiment.

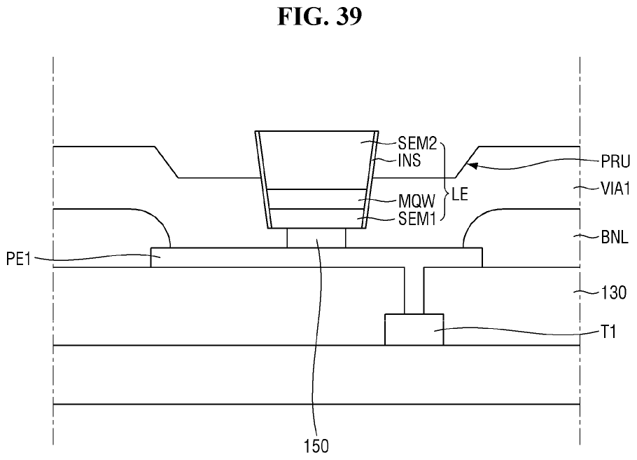

FIGS. 39 to 42 are schematic diagrams illustrating a method of manufacturing a display device according to another embodiment. FIGS. 39 to 42 may substantially each correspond to the cross-sectional views of FIGS. 13 and 14. Since the above-described processes of FIGS. 15 to 30 are the same, subsequent processes will be described.

Referring to FIG. 39, the first via layer VIA1 may be formed on the substrate 110 on which the light emitting elements LE are formed, and the third semiconductor layer of the light emitting element LE may be removed.

An organic material may be applied on the substrate 110 using a solution process such as spin coating, inkjet printing, or the like, and the first via layer VIA1 may be formed using a halftone mask. The first via layer VIA1 may be continuously formed in each of the emission areas. The first via layer VIA1 may be formed to have the protrusion PRU in an area overlapping the bank layer BNL in a plan view. The first via layer VIA1 may be formed to have a height greater than the height of the active layer MQW of the light emitting element LE.

A portion of the insulating layer INS surrounding the light emitting element LE may be removed using a dry etching process, and the exposed third semiconductor layer of the light emitting element LE may be removed using a dry etching process.

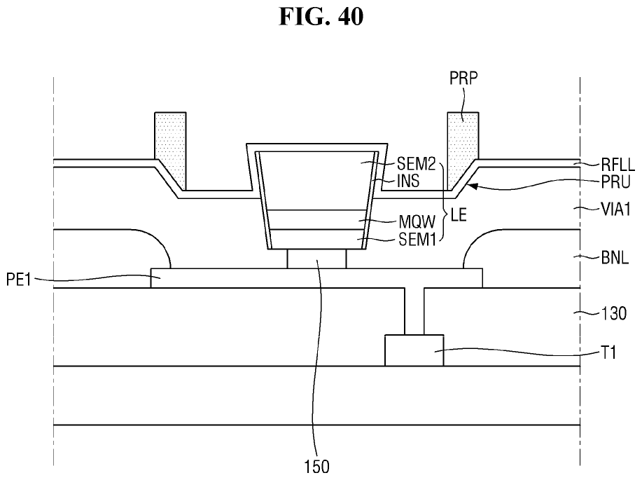

Referring to FIG. 40, the reflective material layer RFLL may be formed on the first via layer VIA1 and a photoresist pattern PRP may be formed on the reflective material layer RFLL.

The reflective material layer RFLL may be formed by forming and stacking a metal on the substrate 110. The reflective material layer RFLL may be stacked on the top surface and side surface of the light emitting element LE and may be extended and stacked on the top surface of the first via layer VIA1.

The photoresist pattern PRP may be formed on the reflective material layer RFLL. The photoresist pattern RPP may be manufactured by applying a photoresist and exposing and developing the photoresist. The photoresist pattern RPP may be formed in an area on which the second reflective layer RFL2 to be described below is to be formed. For example, the photoresist pattern RPP may be disposed to correspond to the side surface of the protrusion PRU of the first via layer VIA1.

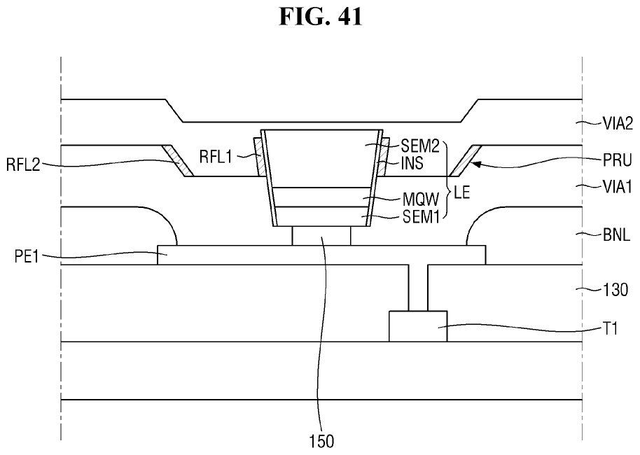

Referring to FIG. 41, a portion of the reflective material layer RFLL may be etched to form the first reflective layer RFL1 and the second reflective layer RFL2.

A process of etching the reflective material layer RFLL may be performed by a process such as dry etching that is anisotropic etching, etchback, or the like. Except for the portion of the reflective material layer RFLL disposed on the side surface of the light emitting element LE and the side surface of the protrusion PRU of the first via layer VIA1, a remaining area of the reflective material layer RFLL may be etched and removed without an additional mask process. An area of the reflective material layer RFLL masked by the photoresist pattern PRP may remain without being removed. Accordingly, the first reflective layer RFL1 disposed on the side surface of the light emitting element LE may be formed, and the second reflective layer RFL2 masked by the photoresist pattern PRP may be formed. The photoresist pattern PRP may be removed.

The second via layer VIA2 may be formed on the light emitting element LE and the first via layer VIA1.

The second via layer VIA2 may be formed by applying an organic material on the substrate 110 using a solution process such as spin coating, inkjet printing, or the like. The second via layer VIA2 may be continuously formed in each of the emission areas. The surface of the second via layer VIA2 may be dry-etched to expose the second semiconductor layer SEM2 of the light emitting element LE.

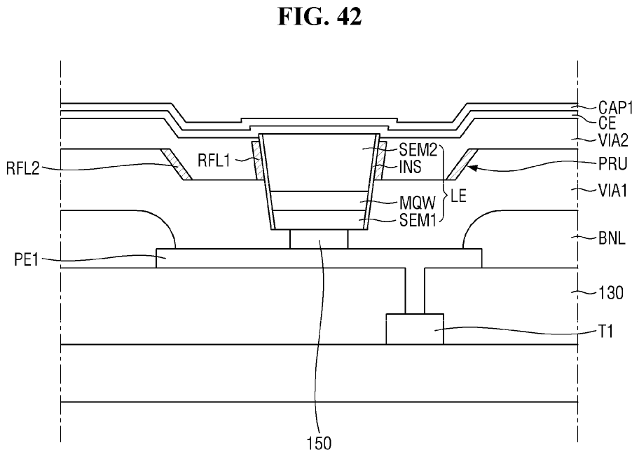

Referring to FIG. 42, the common electrode CE and the first capping layer CAP1 may be sequentially stacked on the light emitting element LE and the second via layer VIA2. The common electrode CE and the first capping layer CAP1 may be formed in the same manner as in the above-described embodiment.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a pixel electrode disposed on a substrate;
a bank layer disposed on the substrate and the pixel electrode and separating an emission area from a non-emission area;
light emitting elements each arranged on the pixel electrode and comprising a first semiconductor layer, a second semiconductor layer, and an active layer disposed between the first semiconductor layer and the second semiconductor layer;
a first capping layer disposed on the pixel electrode and surrounding side surfaces of the light emitting elements;
a first reflective layer disposed on the first capping layer and surrounding the side surfaces of the light emitting elements;
a first via layer disposed on the first reflective layer;
a second via layer disposed on the first via layer; and
a common electrode disposed on the second via layer and the light emitting elements.

2. The display device of claim 1, wherein
each of the light emitting elements further comprises an insulating layer surrounding side surfaces of the first semiconductor layer, the active layer, and the second semiconductor layer, and
the first capping layer contacts the insulating layer.

3. The display device of claim 1, wherein the first reflective layer is spaced apart from the light emitting elements and contacts a surface of the first capping layer.

4. The display device of claim 1, wherein
the first semiconductor layer is disposed adjacent to the pixel electrode, and
the first capping layer and the first reflective layer surround a side surface of the first semiconductor layer, a side surface of the active layer, and a side surface of the second semiconductor layer.

5. The display device of claim 4, wherein the first capping layer and the first reflective layer surround at least a portion of the side surface of the second semiconductor layer.

6. The display device of claim 1, wherein a height of each of the first capping layer and the first reflective layer is less than heights of the light emitting elements.

7. The display device of claim 1, wherein a height of the first capping layer and a height of the first reflective layer are same.

8. The display device of claim 1, wherein the first capping layer and the first reflective layer in the emission area are spaced apart from another first capping layer and another first reflective layer in an adjacent emission area and overlap the emission area in a plan view.

9. The display device of claim 1, wherein
the first via layer contacts a top surface of the first reflective layer, and is spaced apart from an edge of the first reflective layer, and
the second via layer covers the first via layer, the first reflective layer, and the first capping layer.

10. The display device of claim 1, further comprising:
partition walls each disposed on the common electrode and overlapping the bank layer in a plan view;
a second reflective layer disposed on the partition walls;
a wavelength conversion layer disposed between the partition walls; and
a color filter layer disposed on the wavelength conversion layer.

11. A display device comprising:
a pixel electrode disposed on a substrate;
a bank layer disposed on the substrate and the pixel electrode, and separating an emission area from a non-emission area;
light emitting elements each arranged on the pixel electrode and comprising a first semiconductor layer, a second semiconductor layer, and an active layer disposed between the first semiconductor layer and the second semiconductor layer;
a first via layer disposed between the pixel electrode and the light emitting elements;
a first reflective layer disposed on the first via layer and surrounding side surfaces of the light emitting elements;
a second via layer disposed on the first via layer and the first reflective layer; and
a common electrode disposed on the second via layer and the light emitting elements.

12. The display device of claim 11, wherein
each of the light emitting elements further comprises a connection electrode disposed between the pixel electrode and the first semiconductor layer, and
a height of the first via layer and a height of the connection electrode are same.

13. The display device of claim 11, wherein a top surface of the first via layer and a bottom surface of the first semiconductor layer contact each other.

14. The display device of claim 11, wherein
each of the light emitting elements further comprises an insulating layer surrounding side surfaces of the first semiconductor layer, the active layer, and the second semiconductor layer, and
the first reflective layer contacts the insulating layer.

15. The display device of claim 11, wherein the first reflective layer surrounds side surfaces of the first semiconductor layer, the active layer, and the second semiconductor layer.

16. The display device of claim 11, further comprising:
a second reflective layer disposed on the first via layer, wherein
the first via layer comprises a protrusion overlapping the bank layer in a plan view, and
the second reflective layer is disposed on a side surface of the protrusion.

17. The display device of claim 16, wherein
the first reflective layer surrounds a side surface of the second semiconductor layer, and
a bottom surface of the first reflective layer is disposed higher than a top surface of the active layer.

18. The display device of claim 16, wherein each of the first reflective layer and the second reflective layer surrounds the light emitting elements and has a closed loop shape in a plan view.

19. The display device of claim 16, wherein the second reflective layer does not overlap the first semiconductor layer and the active layer in a horizontal direction.

20. The display device of claim 16, wherein a bottom surface of the second reflective layer is disposed higher than a top surface of the active layer.
